(19) United States
(12) Patent Application Publication
(10) Pub. No.: US 2005/0195318 A1
(43) Pub. Date: Sep. 8, 2005

(54) Organic information reading unit and information reading device using the same

(76) Inventors: Takahiro Komatsu, Kasuga-shi (JP); Kei Sakanoue, Fukuoka-shi (JP)

Correspondence Address: WENDEROTH, LIND & PONACK, L.L.P., 2033 K STREET N. W., SUITE 800, WASHINGTON, DC, 20006-1021, US

(21) Appl. No.: 11/084,775

(22) Filed: Mar. 21, 2005

Related U.S. Application Data
(63) Continuation-in-part of application No. 10/772,446, filed on Feb. 6, 2004.

(30) Foreign Application Priority Data
Feb. 7, 2003 (JP) P. 2003-031213
Dec. 26, 2003 (JP) P. 2003-433142
Mar. 23, 2004 (JP) P. 2004-084377

(51) Int. Cl. H04N 5/222; H01L 31/00

(52) U.S. Cl. 348/370; 250/214.1

(57) ABSTRACT

An organic information reading sensor comprising a plurality of light receiving sections for interposing at least one kind of organic material between electrodes and converting a light signal into an electric signal, wherein a non-translucent insulator is provided between the light receiving sections.

### CROSS REFERENCES

This application is a continuation-in-part application of U.S. patent application Ser. No. 10/772,446 filed on Feb. 6, 2004.

### BACKGROUND OF THE INVENTION

The present invention relates to an information reading unit for fetching, as an electric signal, various information such as the shape and image of an object and an information reading device using the information reading unit.

An information reading unit using a photoelectric converting unit for converting optical information into electric information has been used in various products such as a facsimile, a scanner, an electronic blackboard, and furthermore, a fingerprint sensor. Conventionally, an inorganic photodiode, a photoconductor, a phototransistor and their applied components have mainly been used for the photoelectric converting unit section.

An image reading unit to be one of conventional general information reading units will be described with reference to the drawings.

FIG. 29 is a view showing the structure of a conventional optical image reading unit. In FIG. 29, 101 denotes a substrate, 102 denotes a light emitting section, 103 denotes a light receiving section, 104 denotes a rod lens array, and 105 denotes a manuscript.

A light is irradiated on the manuscript 105 by the light emitting section 102 constituted by an LED. The light reflected by the manuscript 105 is guided in an erecting magnification by the rod lens array 104, and is input to the light receiving section 103 constituted by an inorganic photoelectric converting unit and is converted into an electric signal.

In the information reading unit using the conventional inorganic photoelectric converting unit, thus, a method of arranging the light emitting section 102 for irradiating a light on an object such as the manuscript 105 on an oblique side and guiding the light to the light receiving section 103 by using a mirror or a SELFOC lens has been a mainstream.

In the method of irradiating a light on an object in an oblique direction by the light emitting section 102, thus, it is a matter of course that a space is hard to save. In addition, it is necessary to provide the light emitting section 102 and the light receiving section 103 together at an interval from each other. For this reason, only a line sensor having them arranged in a line can be formed. Therefore, various information such as a character, an image or a shape can be read by only a scan through the line sensor. Consequently, it takes a long time to carry out reading and a mechanism for scanning is required so that a cost is increased. Furthermore, a noise in scanning is a problem.

As measures to be taken for saving a space, therefore, a method of laminating a light emitting section and a light receiving section has been proposed to improve a reduction in a thickness as is disclosed in JP-A-04-086155.

Moreover, as is disclosed in JP-A-61-027675, there has also been proposed a method of arranging a photoelectric converting unit like a light shielding substrate provided with an opening portion, thereby irradiating a light from the substrate side through the opening portion.

In an image reading unit described in JP-A-04-086155, however, the light emitting section and the light receiving section are not placed on the same optical axis but are to be provided with a shift from each other in a transverse direction. For this reason, there is a problem in a resolution.

In an image reading unit described in JP-A-61-027675, furthermore, a planar information reading unit can be formed. However, there is a problem in that a process for forming an opening portion is complicated, resulting in an increase in a cost.

### SUMMARY OF THE INVENTION

Therefore, the invention solves the problems and has an object to provide, at a low cost, a small-sized thin information reading unit and an information reading device using the information reading unit.

The invention provides an information reading unit comprising a light emitting section for irradiating a light on an object, and a light receiving section for converting a light reflected from the object into an electric signal, wherein at least a part of the light receiving section has a light transmitting property, and the light receiving section and the light emitting section are laminated.

Consequently, space saving can be carried out, and furthermore, a planar information reading unit can be provided. By utilizing a polarized light as an object irradiating light, moreover, it is possible to provide an information reading unit having a high grade in which a reading performance is further enhanced and an information reading device using the information reading unit.

According to the information reading unit of the invention, the space saving can be carried out. Moreover, it is possible to provide, at a low cost, a thin information reading unit having a high resolution and an information reading device using the information reading unit.

### BRIEF DESCRIPTION OF THE DRAWINGS

FIG. 1 is a schematic perspective view showing an information reading unit according to a first embodiment of the invention,

FIG. 2 is a schematic sectional view showing the main parts of the information reading unit according to the first embodiment of the invention,

FIG. 3 is a schematic sectional view showing the main parts of another information reading unit according to the first embodiment of the invention,

FIG. 4 is a sectional view showing the main parts of an organic electroluminescence unit to be used in the light emitting section of the information reading unit according to the first embodiment of the invention,

FIG. 5 is a sectional view showing main parts according to another example of the organic electroluminescence unit to be used in the light emitting section of the information reading unit according to the first embodiment of the invention,

FIG. 6 is a sectional view showing main parts according to a further example of the organic electroluminescence unit to be used in the light emitting section of the information reading unit according to the first embodiment of the invention,

FIG. 7 is a sectional view showing main parts according to a further example of the organic electroluminescence unit to be used in the light emitting section of the information reading unit according to the first embodiment of the invention,

FIG. 8 is a sectional view showing the main parts of an organic photoelectric converting unit to be used in the light receiving section of the information reading unit according to the first embodiment of the invention,

FIG. 9 is a sectional view showing main parts according to another example of the organic photoelectric converting unit to be used in the light receiving section of the information reading unit according to the first embodiment of the invention,

FIG. 10 is a sectional view showing main parts according to a further example of the organic photoelectric converting unit to be used in the light receiving section of the information reading unit according to the first embodiment of the invention,

FIG. 11 is a sectional view showing main parts according to a further example of the organic photoelectric converting unit to be used in the light receiving section of the information reading unit according to the first embodiment of the invention,

FIG. 12 is a sectional view showing main parts according to a further example of the organic photoelectric converting unit to be used in the light receiving section of the information reading unit according to the first embodiment of the invention,

FIG. 13 is a sectional view showing main parts according to a further example of the organic photoelectric converting unit to be used in the light receiving section of the information reading unit according to the first embodiment of the invention,

FIG. 14 is a schematic sectional view showing the main parts of an information reading unit according to a second embodiment of the invention,

FIG. 15 is a schematic sectional view showing the main parts of the information reading unit according to the second embodiment of the invention,

FIG. 16 is a schematic sectional view showing the main parts of an information reading unit according to a third embodiment of the invention,

FIG. 17 is a schematic sectional view showing the main parts of the information reading unit according to the third embodiment of the invention,

FIG. 18 is a schematic sectional view showing the main parts of the information reading unit according to the third embodiment of the invention,

FIG. 19 is a schematic sectional view showing the main parts of an information reading unit according to a fourth embodiment of the invention,

FIG. 20 is a sectional view showing the main parts of an information reading unit according to a fifth embodiment of the invention,

FIG. 21 is a perspective view showing the main parts of an information reading unit according to a sixth embodiment of the invention,

FIG. 22 is a sectional view showing the main parts of the information reading unit according to the sixth embodiment of the invention,

FIG. 23 is a view for explaining the relationship between the individual light emitting sections and light receiving sections of the information reading unit according to the sixth embodiment of the invention,

FIG. 24(a) is a sectional view showing the main parts of an information reading unit according to a seventh embodiment of the invention and FIG. 24(b) is a plan view showing the main parts of the information reading unit according to the seventh embodiment of the invention,

FIG. 25 is a sectional view showing the main parts of an information reading unit according to an eighth embodiment of the invention,

FIG. 26 is a sectional view showing the main parts of an information reading unit according to a ninth embodiment of the invention,

FIG. 27 is a view showing the structure of an information reading device according to a tenth embodiment of the invention,

FIG. 28 is a sectional view showing the main parts of an information reading unit according to an eleventh embodiment of the invention,

FIG. 29 is a view showing the structure of a conventional optical image reading unit.

FIG. 30 is a perspective view showing an organic information reading module according to a twelfth embodiment of the invention,

FIG. 31 is a sectional view showing the main parts of ordinal organic photoelectric conversion element,

FIG. 32 is a sectional view showing the main part of the organic information reading sensor according to the twelfth embodiment of the invention,

FIG. 33 is a sectional view showing the main part of the organic information reading sensor according to the twelfth embodiment of the invention,

FIG. 34 is a sectional view showing the main part of an organic information reading sensor according to the twelfth embodiment of the invention,

FIG. 35 is a sectional view showing the main part of an organic information reading sensor according to a thirteenth embodiment of the invention,

FIG. 36 is a sectional view showing the main part of an organic information reading sensor according to a fourteenth embodiment of the invention,

FIG. 37 is a sectional view showing the main part of an organic photoelectric converting unit according to a fifteenth embodiment of the invention, and

FIGS. 38(a) to 38(g) show a process for manufacturing an organic information reading sensor according to a sixteenth embodiment of the invention.

### DETAILED DESCRIPTION OF THE PREFERRED EMBODIMENTS

An information reading unit according to the invention will be described below in detail.

### First Embodiment

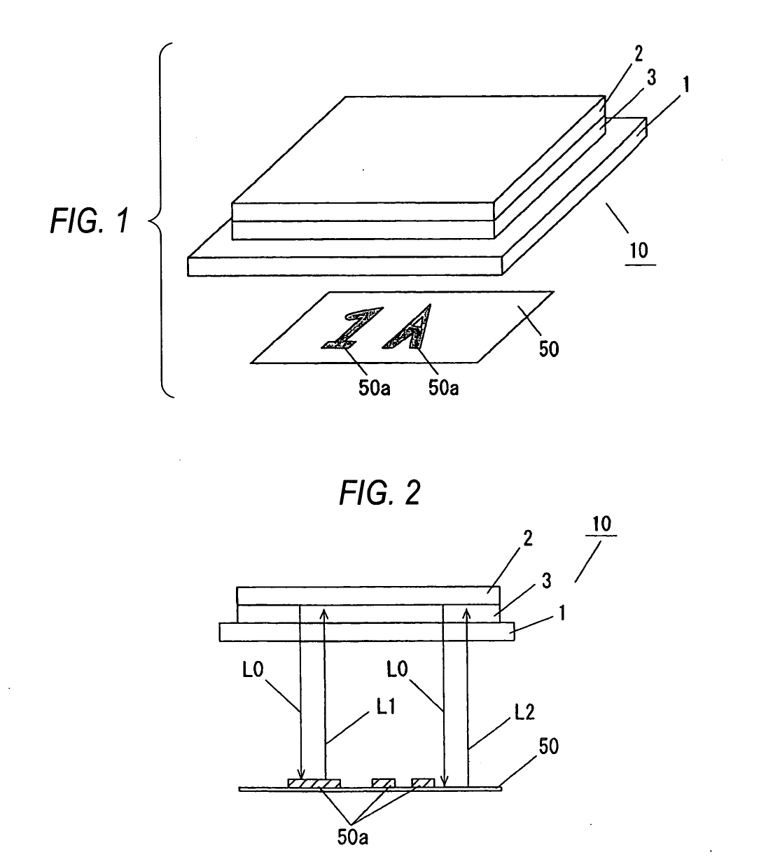

FIG. 1 is a schematic perspective view showing an information reading unit according to a first embodiment of the invention, and FIG. 2 is a schematic sectional view showing the main parts of the information reading unit according to the first embodiment of the invention.

In FIGS. 1 and 2, 1 denotes a substrate, 2 denotes a light emitting section, 3 denotes a light receiving section, and 10 denotes an information reading unit. Moreover, 50 denotes an object and 50a denotes information. Arrows L0, L1 and L2 in FIG. 2 denote a beam.

The substrate 1 serves to support the light emitting section 2 and the light receiving section 3, and the light emitting section 2 is a light source for discharging a light for illuminating the object 50 and the light receiving section 3 receives a light reflected from the object 50 and converts the light into an electric signal. Furthermore, the object 50 records the information 50a and the object 50 includes a manuscript in which visible information such as characters or graphics are recorded on a base material such as a paper.

As shown in FIGS. 1 and 2, a structure to be the basis of the information reading unit 10 includes the light emitting section 2 for irradiating a light on the object 50 and the light receiving section 3 for converting a light reflected from the object 50 into an electric signal.

In the information reading unit 10, the light receiving section 3 has a light transmitting property. As shown in FIGS. 1 and 2, the light emitting section 2 and the light receiving section 3 are provided so as to have regions which are superposed on at least the same optical axis, that is, to cause the light receiving region of the light receiving section 3 to be superposed on the light emitting region of the light emitting section 2 in the direction of the optical axis.

Thus, the light emitting section 2 and the light receiving section 3 are laminated on each other. As compared with the information reading unit including the light emitting section 102 and the light receiving section 103 which are provided independently of each other as described in the conventional art, a size and a thickness can be reduced considerably.

Moreover, information reading will be briefly described. A light discharged from the light emitting section 2 passes through the light receiving section 3 and the substrate 1 and is irradiated on the object 50 as shown in the beam L0. Then, the irradiated light is reflected by the object 50. At this time, the intensity of the reflected light is varied depending on the presence of the information 50a over the object 50. Description will be given on the assumption that the reflectance of the irradiated light in the information 50a is lower than that in other regions (the absorption of the irradiated light in the information 50a is greater than that in other regions on the object 50). The light reflected by the information 50a passes through the substrate 1 and is incident on the light receiving section 3 as shown in the beam L1. Moreover, the light reflected in a region in which the information 50a is not present passes through the substrate 1 and is incident on the light receiving section 3 as shown in the beam L2. When these reflected lights are received, a current corresponding to each of the reflected lights flows to a photoelectric converting unit constituting the light receiving section 3. At this time, the light reflected by the information 50a is weak and the current is smaller than a current generated by the light reflected in the other regions. In the light receiving section 3, accordingly, a difference in the intensity of the reflected light which is made by the presence of the information 50a in the object 50 can be output as a difference in the current corresponding thereto, and the presence of the information 50a, that is, the information recorded on the object 50 can be read.

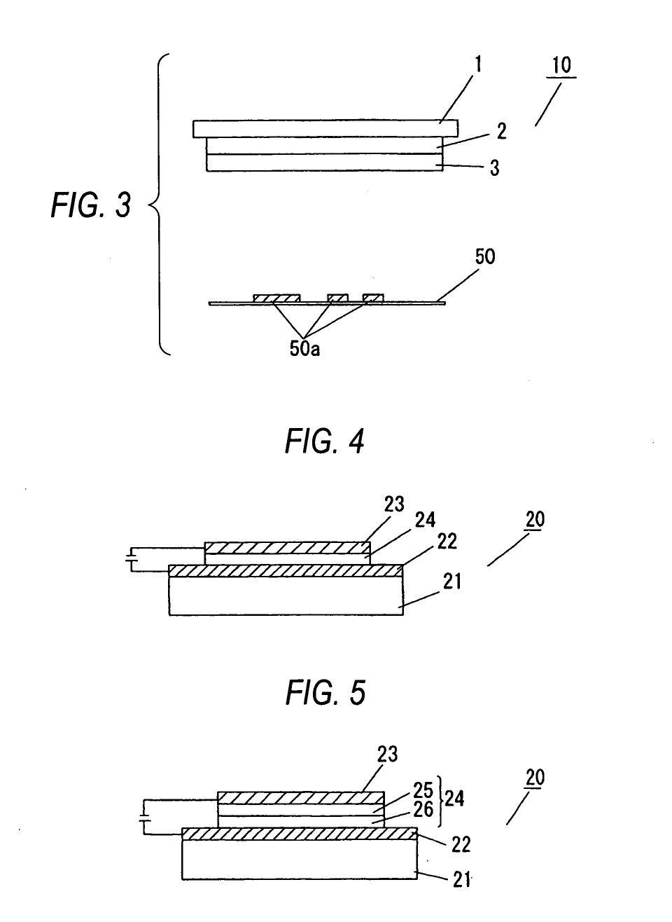

FIG. 3 is a schematic sectional view showing the main parts of another information reading unit according to the first embodiment of the invention. In FIG. 3, the same portions as those in FIGS. 1 and 2 have the same reference numerals. Also in the subsequent drawings, furthermore, the same portions as those described above have the same reference numerals. In some cases in which description is repeated, it is partially omitted.

While the information reading unit 10 has such a structure that the light receiving section 3 and the light emitting section 2 are provided on the substrate 1 in this order and the substrate 1 is provided on the object 50 side to carry out reading in the case shown in FIG. 2, the light emitting section 2 and the light receiving section 3 may be provided on the substrate 1 in this order and the substrate 1 may be provided on a reverse side to the object 50, thereby carry out the reading as shown in FIG. 3.

Next, each structure of the information reading unit 10 according to the first embodiment of the invention will be described in more detail.

First of all, preferably, the substrate 1 has a mechanical and thermal strength, and furthermore, is not optically deteriorated by a light irradiated from the light emitting section 2, and is not particularly restricted.

For the substrate 1, it is possible to use a material having a high transparency in a visible light region, for example, a glass substrate, polyethylene terephthalate, polycarbonate, polymethyl methacrylate, polyether sulfone, polyvinyl fluoride, polypropylene, polyethylene, polyacrylate, amorphous polyolefine or fluororesin, and a flexible substrate having a flexibility which is obtained by changing these materials into films. The substrate 1 preferably has a light transmitting property in the case shown in FIG. 2, and the light transmitting property is not always required in the case shown in FIG. 3.

While the substrate 1 preferably has an insulating property, moreover, it is not particularly restricted but may have a conductive property within a range in which the operation of the information reading unit 10 is not disturbed or depending on applications.

Next, the light emitting section 2 will be described. If the light emitting section 2 has such a light quantity and wavelength as to irradiate a light on an object and to introduce the reflected light into the light receiving section 3, thereby obtaining information, it is not particularly restricted. A light emitting diode, a laser, and a cooling electrode tube can be used, and a planar light emitting unit such as an inorganic electroluminescence unit or an organic electroluminescence unit is preferable in consideration of space saving.

Description will be given to the organic electroluminescence unit to be used as the light emitting section 2.

FIG. 4 is a sectional view showing the main parts of the organic electroluminescence unit to be used in the light emitting section of the information reading unit according to the first embodiment of the invention. In FIG. 4, 20 denotes an organic electroluminescence unit, 21 denotes a substrate, 22 denotes an anode, 23 denotes a cathode, and 24 denotes an organic thin film layer having a light emitting region.

As shown in FIG. 4, for example, the organic electroluminescence unit 20 includes the anode 22 formed by a transparent conductive film such as ITO which is provided on the transparent or translucent substrate 21 such as a glass by a sputtering process or a resistance heating deposition process, the organic thin film layer 24 having a light emitting region comprising 8-Hydroxyquinoline Aluminum (hereinafter referred to as Alq₃) formed by the resistance heating deposition process over the anode 22, and the cathode 23 to be a metal film having a thickness of 100 nm to 300 nm which is formed by the resistance heating deposition process over the organic thin film layer 24.

When the anode 22 and the cathode 23 in the organic electroluminescence unit having the structure are set to be plus and minus electrodes respectively to apply a DC voltage or a direct current, a hole is injected from the anode 22 to the organic thin film layer 24 and an electron is injected from the cathode 23 to the organic thin film layer 24. In the organic thin film layer 24, the recombination of the hole and the electron is generated. When an exciton generated correspondingly is to be changed from an excitation state to a base state, a luminous phenomenon is caused.

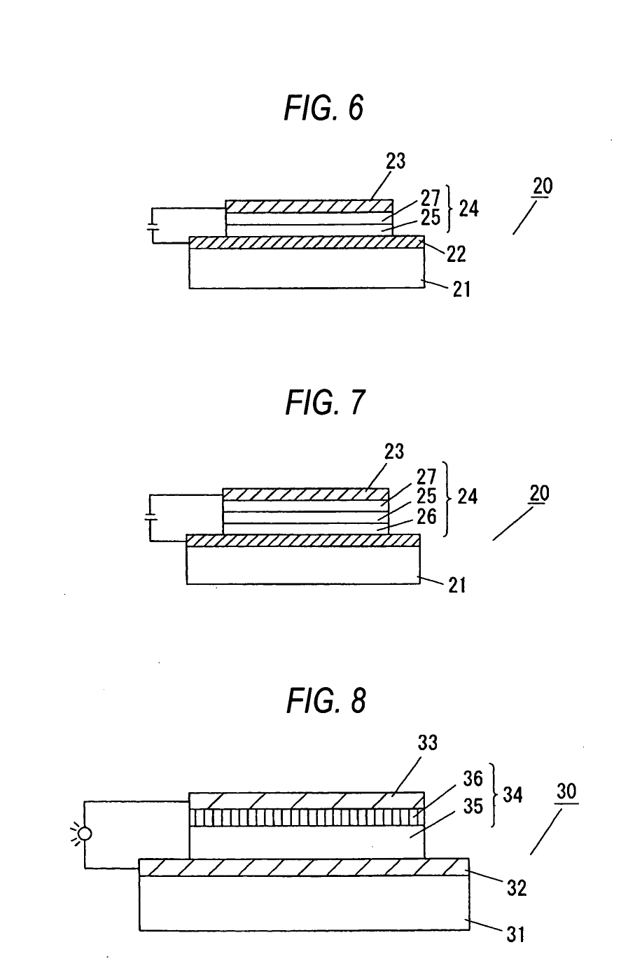

FIGS. 5, 6 and 7 are sectional views showing main parts according to another example of the organic electroluminescence unit to be used in the light emitting section of the information reading unit according to the first embodiment of the invention. 25 denotes a light emitting layer and 26 denotes a hole transporting layer in FIG. 5, and 27 denotes an electron transporting layer in FIG. 6.

As shown in FIG. 5, the organic thin film layer 24 may be constituted by the hole transporting layer 26 and the light emitting layer 25 having a light emitting region. As shown in FIG. 6, the organic thin film layer 24 may be constituted by the light emitting layer 25 having the light emitting region and the electron transporting layer 27. Alternatively, the organic thin film layer 24 may be constituted by the hole transporting layer 26, the light emitting layer 25 having the light emitting region, and the electron transporting layer 27 as shown in FIG. 7. In the case shown in FIG. 4, moreover, the organic thin film layer 24 is constituted by a single layer of the light emitting layer 25.

While the anode 22 is formed on the substrate 21 and the organic thin film layer 24 and the cathode 23 are sequentially formed thereon in FIGS. 4 to 7, it is also possible to employ a structure in which the cathode 23 is formed on the substrate 21 and the organic thin film layer 24 and the anode 22 are sequentially formed.

Irrespective of the positional relationship and layer structure of the substrate 21, it is sufficient that the organic electroluminescence unit 20 includes at least the organic thin film layer 24 having the light emitting region which is formed between the two electrodes, that is, the anode 22 and the cathode 23.

The substrate 21 of the organic electroluminescence unit 20 may be transparent or translucent, or may be opaque if it is not used as a light take-out surface. It is sufficient that the substrate 21 has such a strength as to hold the organic electroluminescence unit 20. For the definition of the transparency or translucency, the object 50 is illuminated by the light emission of the organic electroluminescence unit 20 and such a transparency as to carry out reading by the light receiving section 3 for receiving the reflected light is obtained.

For example, the substrate 21 can be properly selected for use from a transparent or translucent inorganic glass, that is, an inorganic oxide glass such as a soda-lime glass, a barium-strontium containing glass, a lead glass, an aluminosilicate glass, a borosilicate glass, a barium borosilicate glass or a quartz glass, or an inorganic fluoride glass, a transparent or translucent polymer film such as polyethylene terephthalate, polycarbonate, polymethyl methacrylate, polyether sulfone, polyvinyl fluoride, polypropylene, polyethylene, polyacrylate, amorphous polyolefin or fluororesin, a transparent or translucent chalcogenoide glass such as As₂S₃, As₄₀S₁₀ or S₄₀Ge₁₀, a material such as metal oxides and nitrides, for example, ZnO, Nb₂O, Ta₂O₅, SiO, Si₃N₄, HfO₂ or TiO₂, a translucent semiconductor material such as silicon, germanium, silicon carbide, gallium arsenic or gallium nitride, or the transparent substrate material containing a pigment, or a metal material having a surface subjected to an insulating process, and it is also possible to use a laminated substrate having a plurality of substrate materials laminated thereon.

Moreover, it is also possible to form a circuit comprising a resistor, a capacitor, an inductor, a diode and a transistor which serve to drive the organic electroluminescence unit 20 on the surface of the substrate 21 or the inner part of the substrate 21.

Depending on applications, furthermore, it is also possible to use a material for transmitting only a light having a specific wavelength therethrough or a material for carrying out a conversion to a light having a specific wavelength with a light-light converting function. While it is preferable that the substrate 21 should have an insulating property, moreover, it is not particularly restricted but may have a conductivity within a range in which the driving operation of the organic electroluminescence unit 20 is not disturbed or depending on the applications.

For the anode 22 of the organic electroluminescence unit 20, ITO (an indium-tin oxide), ATO (SnO₂ doped with Sb) and AZO (ZnO doped with Al) are used.

It is preferable that the light emitting layer 25 of the organic electroluminescence unit 20 should have a fluorescent or phosphorescent property in a visible region and have an excellent film forming property. In addition to Alq₃ and Be-benzoquinolinol (BeBq₂), there is used a fluorescent brightening agent such as a benzooxazol type, for example, 2,5-bis(5,7-di-t-pentyl-2-benzooxazolyl)-1,3,4-thiadiazol, 4,4′-bis(5,7-pentyl-2-benzooxazolyl) stilbene, 4,4-bis[5,7-di-(2-methyl-2-butyl)-2-benzooxazolyl]stilbene, 2,5-bis(5,7-di-t-pentyl-2-benzooxazolyl)thiophin, 2,5-bis([5-a,a-dimethylbenzyl]-2-benzooxazolyl)thiophen, 2,5-bis[5,7-di-(2-methyl-2-butyl)-2-benzooxazolyl-3,4-diphenylthiophen, 2,5-bis(5-methyl-2-benzooxazolyl)thiophen, 4,4′-bis(2-benzooxazolyl)biphenyl, 5-methyl-2-[2-[4-(5-methyl-2-benzooxazolyl)phenyl]vinyl]benzooxazolyl or 2-[2-(4-chlorophenyl)vinyl]naphtho[1,2-d]oxazol, a benzothiazol type, for example, 2,2′-(p-phenylenedivinylene)-bisbenzothiazol, or a benzoimidazol type, for example, 2-[2-[4-(2-benzoimidazolyl)phenyl]vinyl]benzoimidazol or 2-[2-(4-carboxyphenyl) vinyl]benzoimidazol, an 8-hydroxyquinoline type metal complex such as tris(8-quinolinol) aluminum, bis(8-quinolinol) magnesium, bis(benzo[f]-8-quinolinol) zinc, bis(2-methyl-8-quinolinolate) aluminum oxide, tris(8-quinolinol) indium, tris(5-methyl-8-quinolinol) aluminum, 8-quinolinol lithium, tris(5-chloro-8-quinolinol) gallium, bis(5-chloro-8-quinolinol) calcium or poly[zinc-bis(8-hydroxy-5-quinolinonyl) methane], a metal chelating oxynoide compound such as dilithium epindrydione, a styrylbenzene type compound, for example, 1,4-bis(2-methylstyryl)benzene, 1,4-(3-methylstyryl)benzene, 1,4-bis(4-methylstyryl)benzene, distyrylbenzen, 1,4-bis(2-ethylstyryl)benzene, 1,4-bis(3-ethylstyryl)benzene, 1,4-bis(2-methylstyryl) 2-methylbenzene, a distilpyrazine derivative such as 2,5-bis(4-methylstyryl)pyrazine, 2,5-bis(4-ethylstyryl)pyrazine, 2,5-bis[2-(1-naphtyl)vinyl]pyrazine, 2,5-bis (4-methoxystyryl)pyrazine, 2,5-bis[2-(4-biphenyl)vinyl]pyrazine or 2,5-bis[2-(1-pyrenyl) vinyl]pyrazine, a naphthalimide derivative, a perylene derivative, an oxadiazol derivative, an aldadine derivative, a cyclopentadiene derivative, a styrylamine derivative, a coumalin type derivative, or an aromatic dimethyldine derivative. Furthermore, anthracene, salicylate, pyrene, and coronene are also used. Alternatively, it is also possible to use a phosphorescent light emitting material such as fac-tris(2-phenylpyridine) iridium or a polymer light emitting material such as PPV (polyparaphenylenevinylene) or polyfluorene.

Moreover, it is preferable that the hole transporting layer 26 of the organic electroluminescence unit 20 should have a high hole mobility and is transparent and excellent in a film forming property, and there are used organic materials, for example, a polyphyrin compound such as N,N′-diphenyl-N,N′-bis(3-methylphenyl)-1,1′-diphenyl-4,4′-diamine (TPD), and furthermore, porphin, tetraphenylporphin copper, phthalocyanine, copper phthalocyanine or titanium phthalocyanine oxide, aromatic tertiary amine such as 1,1′-bis[4-(di-P-tolylamino)phenyl]cyclohexane, 4,4′,4″-trimethyltriphenylamine, N,N,N′,N′-tetrakis(P-tolyl)-P-phenylenediamine, 1-(N,N-di-P-tolylamino)naphthalene, 4,4′-bis(dimethylamino)-2-2′-dimethyltriphenylmethane, N,N,N′,N′-tetraphenyl-4,4′-diaminobiphenyl, N,N′-diphenyl-N,N′-di-m-tolyl-4,4′-diaminophenyl, or N-phenylcarbazole, a stilbene compound such as 4-di-P-tolylamino stilbene, 4-(di-P-tolylamino)-4′-[4-(di-P-tolylamino) styryl]stilbene, a triazole derivative, an oxadizazole derivative, an imidazole derivative, a polyarylalkane derivative, a pyrazoline derivative, a pyrazolone derivative, a phenylenediamine derivative, an anilamine derivative, an amino substituted chalcone, derivative, an oxazole derivative, a styrylanthracene derivative, a fluorenon derivative, a hydrazone derivative, a silazane derivative, a polysilane type aniline type copolymer, polymer oligomer, a styrylamine compound, an aromatic dimethylidine type compound, or a polythiophene derivative, for example, poly-3,4-ethylenedioxythiophene (PEDOT) or poly-3-methylthiophene (PMeT). Moreover, there is also used a polymer dispersion type hole transporting material in which a low molecular organic material for hole transportation is dispersed in a polymer such as polycarbonate. In addition, these hole transporting materials can also be used for hole injecting materials or electron block materials.

Furthermore, a polymer material comprising an oxadiazole derivative, for example, 1,3-bis(4-tert-butylphenyl-1,3,4-oxadiazolyl)phenylene (OXD-7), an anthraquinodimethane derivative, a diphenylquinone derivative or a sirol derivative for the electron transporting layer 27 of the organic electroluminescence unit 20. Moreover, these electron transporting materials can also be used as an electron injection material or a hole block material.

In the case in which the organic thin film layer 24 (the light emitting layer 25 or the hole transporting layer 26 or the electron transporting layer 27 which is formed if necessary), is to be formed by a polymer material, it is also possible to use a wet film forming method such as a spin coating process, a casting process, a dipping process, a bar code process or a roll coating process. Consequently, a large-scale vacuum device is not required. For this reason, a film can be formed by inexpensive equipment, an organic electroluminescence unit having a large area can easily be fabricated, and furthermore, an adhesion between the layers of the organic electroluminescence unit can be enhanced. Consequently, a short circuit in the unit can be suppressed and the organic electroluminescence unit 20 having a high stability can be formed.

Moreover, a metal or an alloy having a low work function is used, and a metal such as Al, In, Mg or Ti, an Mg alloy such as an Mg—Ag alloy or an Mg—In alloy, and an Al alloy such as an Al—Li alloy, an Al—Sr alloy or an Al—Ba alloy are used for the cathode 23 in the organic electroluminescence unit 20.

Thus, a simple structure is employed. Therefore, a thickness and a size can be reduced, and furthermore, a variation in an illuminance on an object can be suppressed by a planar light emission having a high luminance, and the formation can be carried out by an applying method and a cost can also be reduced. Consequently, the organic electroluminescence unit 20 is suitable for a light source for an optical information reading unit.

Next, the light receiving section 3 will be described. The light receiving section 3 may be various units for carrying out a photoelectric conversion which have a light transmitting property, and can receive a light reflected from the object 50 and can convert the same light into an electric signal, and is not particularly restricted. It is preferable to use a photoelectric converting unit and a photoconductive unit which will be described below.

Description will be given to the photoelectric converting unit to be used as the light receiving section 3.

FIG. 8 is a sectional view showing the main parts of an organic photoelectric converting unit to be used in the light receiving section of the information reading unit according to the first embodiment of the invention. In FIG. 8, 30 denotes an organic photoelectric converting unit. Moreover, 31 denotes a substrate, 32 denotes an anode, 33 denotes a cathode, 34 denotes a photoelectric converting region, 35 denotes an electron donating layer constituted by an electron donating organic material, and 36 denotes an electron accepting layer constituted by an electron accepting material.

As shown in FIG. 8, the organic photoelectric converting unit 30 will be described by taking an example. The organic photoelectric converting unit 30 comprises the anode 32 comprising a transparent conductive film such as ITO which is formed on a light transmitting substrate 31 such as a glass by a sputtering process or a resistance heating deposition process, the photoelectric converting region 34 having the electron donating layer 35 and the electron accepting layer 36 formed on the anode 32 by a resistance heating deposition process respectively, and furthermore, the cathode 33 formed of a metal thereon by the resistance heating deposition process.

When a light is irradiated on the organic photoelectric converting unit 30 having such a structure, a light absorption is caused in the photoelectric converting region 34 so that an exciton is formed. Subsequently, a carrier is separated, and an electron is moved to the cathode 33 through the electron accepting layer 36, and a hole is moved to the anode 32 through the electron donating layer 35. Consequently, an electromotive force is generated between both electrodes and an external circuit is connected so that a power can be fetched. FIG. 8 typically shows a state in which an electric lamp emits a light and a power is fetched.

In the organic photoelectric converting unit 30, the presence or difference of the electromotive force is caused by the presence of a light irradiation and a difference in a light intensity. In the case in which the organic photoelectric converting unit 30 is used in the light receiving section 3 of the information reading unit 10, a difference in the intensity of a reflected light which is made by the presence of the information 50a of the object 50 can be output as a difference in an electromotive force which is made corresponding thereto.

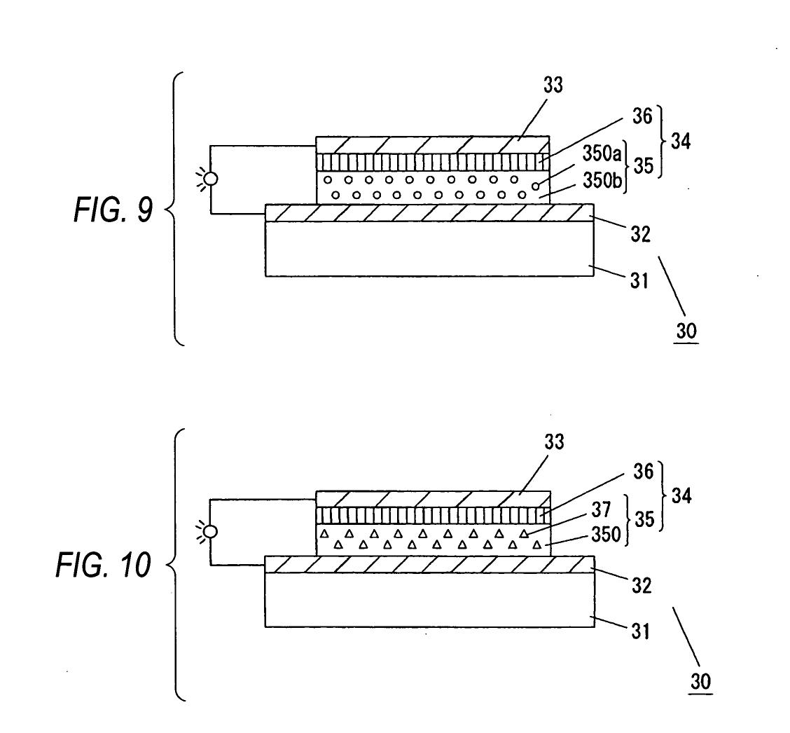

Furthermore, description will be given to another example of the photoelectric converting unit 30 to be used as the light receiving section 3. FIG. 9 is a sectional view showing main parts according to another example of the organic photoelectric converting unit to be used in the light receiving section of the information reading unit according to the first embodiment of the invention. In FIG. 9, 350a and 350b denote electron donating organic materials, respectively.

In the organic photoelectric converting unit 30 shown in FIG. 9, an electron donating layer 35 of a photoelectric converting region 34 contains two types of electron donating organic materials 350a and 350b. The electron donating organic material 350a and the electron donating organic material 350b have different absorbing wavelength properties from each other.

Description will be given to advantages produced by the provision of the electron donating layer 35 containing the electron donating organic material 350a and the electron donating organic material 350b which have different absorbing wavelength properties from each other in the photoelectric converting region 34 of the organic photoelectric converting unit 30. The energy conversion efficiency of the organic photoelectric converting unit 30 is greatly influenced by the amount of absorption of an incident light. Therefore, the light absorbing property of the photoelectric converting region 34 is very important. Moreover, it is effective that the type of a material to be used is changed to adapt an absorption spectrum to an incident light spectrum in order to increase the amount of absorption of an optical energy, and furthermore, a thickness is increased. However, in the case in which a light emitting source having a light emitting wavelength region within a wide range is used for the light emitting section 2, for example, it is hard to absorb the whole light by only one type of electron donating organic material. Moreover, an increase in the thickness of the photoelectric converting region 34 can easily increase the amount of absorption of the light and brings about an adverse effect that the increase in the thickness reduces the fetching efficiency of a carrier. By constituting the electron donating layer 35 using the two types of electron donating organic materials 350a and 350b, therefore, it is possible to absorb a light in a wide wavelength region. By blending a plurality of p-conjugated system polymer materials having different maximum absorption wavelengths to be used as the electron donating organic materials 350a and 350b, particularly, the absorption efficiency of an incident light can be enhanced, and a carrier transportation efficiency can be improved and the organic photoelectric converting unit 30 can have a high efficiency, which is preferable.

The electron donating layer 35 preferably contains at least two types of electron donating organic materials 350a and 350b, and can also be formed by at least three types of electron donating organic materials. In case of the three types or more, the wavelength properties to be absorbed by the respective electron donating organic materials are set to be varied so that a light in a wavelength region within a wider range can be absorbed.

Moreover, the electron donating layer 35 contains at least two types of electron donating organic materials 350a and 350b. By absorbing a light in a wavelength region within a wide range, consequently, the absorption efficiency of an incident light can be enhanced. In the case in which the light emitting section 2 is constituted by a plurality of light emitting sources having different light emitting wavelengths from each other or the light emitting source of the light emitting section 2 can selectively change a light emitting wavelength depending on applications, the electron donating organic materials 350a and 350b having different absorption wavelengths generate electromotive forces corresponding to a wavelength irradiated from the light emitting section 2 respectively. Accordingly, an output can be carried out corresponding to the wavelength of the light emitting section 2. Therefore, the wavelength of the light emitting section 2 can be distinguished in the light receiving section 3.

Furthermore, description will be given to another example of the photoelectric converting unit 30 to be used as the light receiving section 3. FIG. 10 is a sectional view showing main parts according to another example of the organic photoelectric converting unit to be used in the light receiving section of the information reading unit according to the first embodiment of the invention. In FIG. 10, 350 denotes an electron donating organic material and 37 denotes a light-light converting material.

In the organic photoelectric converting unit 30 shown in FIG. 10, the electron donating layer 35 of the photoelectric converting region 34 has such a structure that the electron donating organic material 350 contains at least one type of light-light converting material 37.

Description will be given to advantages produced by the provision of the electron donating layer 35 containing at least one type of light-light converting material 37 in the electron donating organic material 350 in the photoelectric converting region 34 of the organic photoelectric converting unit 30. In order to increase the conversion efficiency of the organic photoelectric converting unit 30, an enhancement in the absorption efficiency of an incident light is indispensable. Even if the electron donating organic materials are used, however, an incident light spectrum and the absorption property of the electron donating organic material cannot be always optimized. In the case in which a light emitting source in which a light emitting wavelength has an ultraviolet region is used for the light emitting section 2 depending on applications, it is substantially hard to directly absorb a light in the ultraviolet region in consideration of the durability of the material. In such a case, the electron donating organic material 350 of the photoelectric converting region 34 is provided to contain the light-light converting material 37, thereby carrying out a conversion to a wavelength in a region which can be absorbed by the electron donating organic material 350. Under a situation in which the spectral width of an incident light is small and the wavelength is hard to change, a method of adapting the absorption property of the light receiving section 3 into the incident light by the light-light converting material 37 is very effective means for enhancing the conversion efficiency.

For the light-light converting material 37, it is also possible to use any material capable of absorbing an incident light more efficiently than the electron donating organic material 350 and effectively moving an excitation energy to the electron donating organic material 350 or an electron accepting layer 36. In order to obtain a high conversion efficiency, it is preferable to use a material which absorbs a light having a shorter wavelength than that of the electron donating organic material 350, and a high fluorescent quantum efficiency and a small thermal inactivation process in an excitation state. For example, coumalin or rhodamine can be used for the light-light converting material 37.

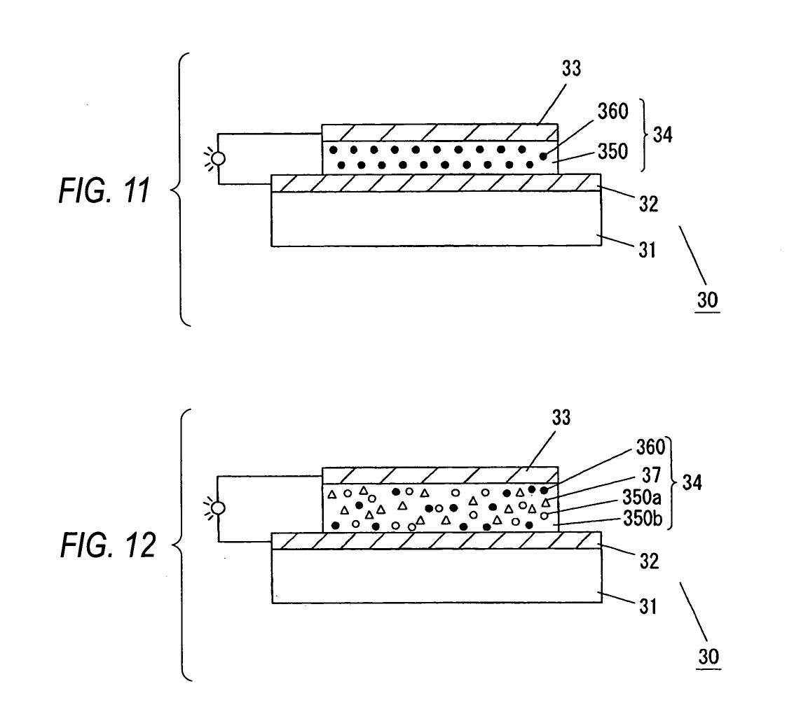

Furthermore, description will be given to a further example of the photoelectric converting unit 30 to be used as the light receiving section 3. FIG. 11 is a sectional view showing main parts according to a further example of the organic photoelectric converting unit to be used in the light receiving section of the information reading unit according to the first embodiment of the invention. In FIG. 11, 360 denotes an electron accepting material. It is preferable that fullerenes and carbon nano tubes should be used singly or in mixture for the electron accepting material 360.

In the organic photoelectric converting unit 30 shown in FIG. 11, a photoelectric converting region 34 is constituted by mixing the electron accepting material 360 with an electron donating organic material 350. Thus, the photoelectric converting region 34 is constituted by the mixture of the electron accepting material 360 and the electron donating organic material 350. The “mixture” is obtained by putting a liquid or solid material in a container and adding a solvent, and stirring and mixing them if necessary and forming them into a film by a spin coating process.

The organic photoelectric converting unit 30 of the mixture type carries out a light absorption, an excitation and an electron transfer in the whole photoelectric converting region 34, and has a comparatively high conversion efficiency with a very simple structure.

In addition, the absorption property and the structure of the unit are given. Consequently, the organic photoelectric converting unit 30 can have the conversion efficiency enhanced still more.

As shown in FIG. 12, particularly, a plurality of electron donating organic materials 350a and 350b having different wavelength properties to be absorbed from each other, the electron accepting material 360, and furthermore, the light-light converting material 37 are mixed and used for the photoelectric converting region 34 so that the organic photoelectric converting unit 30 having a high conversion efficiency can be obtained. FIG. 12 is a sectional view showing main parts according to a further example of the organic photoelectric converting unit to be used in the light receiving section of the information reading unit according to the first embodiment of the invention.

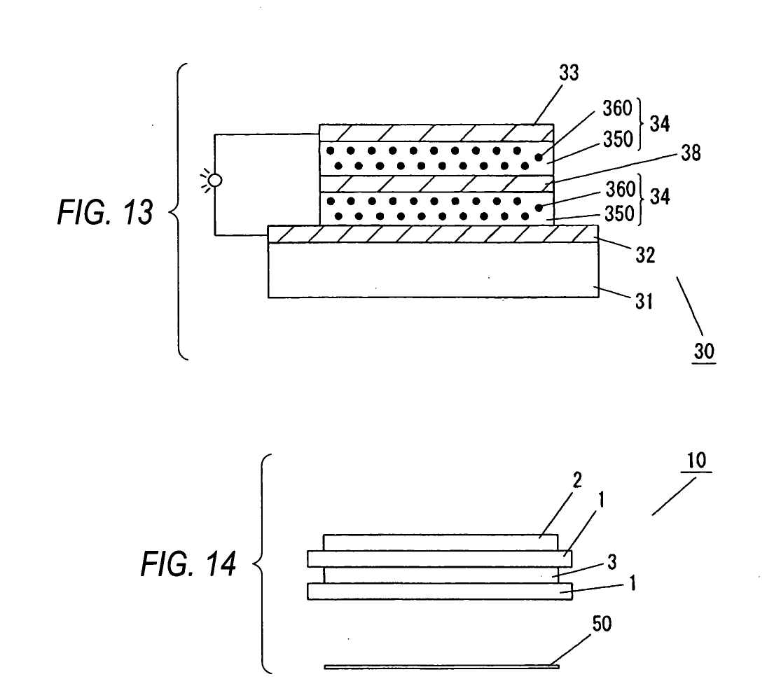

Moreover, the photoelectric converting region 34 described above may be formed by a single layer or plural layers. FIG. 13 is a sectional view showing main parts according to a further example of the organic photoelectric converting unit to be used in the light receiving section of the information reading unit according to the first embodiment of the invention.

As shown in FIG. 13, the organic photoelectric converting unit 30 may comprise the photoelectric converting region 34 in at least two layers.

In this case, moreover, the wavelength property to be absorbed by the electron donating organic material 350 included in each of the photoelectric converting regions 34 is varied so that a unit having the photoelectric converting regions 34 constituted in a plurality of stages and them connected electrically in series can enhance an open end voltage. Thus, the organic photoelectric converting unit 30 includes the photoelectric converting regions 34 having different absorption wavelengths from each other which are constituted in a plurality of stages. Therefore, it is possible to considerably increase the amount of a light absorption as a whole.

In the case in which an electrode 38 is provided between the photoelectric converting regions 34 in the lamination of the photoelectric converting regions 34 as shown in FIG. 13, a sufficient light transmitting property is required, and furthermore, both an anode and a cathode is to function. Moreover, the electrode 38 is provided between the photoelectric converting regions 34 if necessary.

Thus, it is sufficient that the basic structure of the organic photoelectric converting unit 30 has the photoelectric converting region 34 between at least two electrodes and a substrate 31 for supporting the structure of these units is provided. The electrode includes an anode 32 and a cathode 33, and the photoelectric converting region 34 includes at least the electron donating organic material 350 and an electron accepting material 360. Moreover, the photoelectric converting region 34 may have a structure in which a region formed by the electron donating organic material 350 and a region formed by the electron accepting material 360, or a structure in which the electron donating organic material 350 and the electron accepting material 360 are mixed with each other, or a structure in which the region formed by the electron donating organic material 350 includes the electron accepting material 360.

The substrate 31 to be used in the organic photoelectric converting unit 30 has a mechanical and thermal strength. If the substrate 31 effectively transmits an irradiated light emitted from a light emitting section 2, it is not particularly restricted.

For example, it is possible to use a material having a high transparency for a visible light region such as a glass, poethyleneterephthalate, polycarbonate, polymethylmethacrylate, polyethersulfone, polyvinyl fluoride, polypropylene, polyethylene, polyacrylate, amorphous polyolefin or fluororesin, and a flexible substrate having a flexibility in which these materials are changed into a film. In the case in which a polymer material is used, moreover, it is also effective that a coat formed of various metals or metal oxides is provided on the external surface of the substrate so as not to reduce a transmittance if possible in order to enhance a moisture resistance.

Furthermore, it is possible to use a material for transmitting only a specific wavelength depending on applications or a material for carrying out a conversion into a light having a specific wavelength with a light-light converting function. While it is preferable that the substrate should have an insulating property, moreover, it is not particularly restricted but may have a conductivity within a range in which the operation of the organic photoelectric converting unit is not disturbed or depending on the applications.

While the organic photoelectric converting unit 30 has a structure in which the photoelectric converting region 34 is provided between at least two electrodes, at least a part of a light receiving section 3 is to have a light transmitting property. The transmittance greatly influences a photoelectric converting property.

For the anode 32 of the organic photoelectric converting unit 30, therefore, there is used a so-called general transparent electrode obtained by forming ITO, ATO (SnO₂ doped with Sb) or AZO (ZnO doped with Al) by a sputtering process or an ion beam evaporation process. Moreover, it is also possible to use various metal material thin films such as Au and Ag or various conductive polymer compounds such as application type ITO, PEDOT, PPV and polyfluorene having a comparatively high resistance by the provision of an auxiliary electrode.

Moreover, the cathode 33 to be used in the organic photoelectric converting unit 30 is to efficiently take out a generated electric charge into an external circuit and at least a part has a light transmitting property as the light receiving section 3. Therefore, there is used a thin film such as a metal, for example, Al, Au, Cr, Cu, In, Mg, Ni, Si or Ti, an Mg alloy, for example, an Mg—Ag alloy or an Mg—In alloy, or an Al alloy, for example, an Al—Li alloy, an Al—Sr alloy or an Al—Ba alloy. In order to improve a short-circuit current, moreover, it is also possible to suitably use a method of introducing a thin film such as a metal oxide or a metal fluoride between the photoelectric converting region 34 and the cathode 33. Furthermore, it is also possible to use ITO, ATO or AZO.

By providing an auxiliary electrode constituted by a metal material having a low resistance together with the anode 32 and the cathode 33, moreover, it is possible to use a material having a comparatively high resistance such as a conductive polymer compound, for example, application type ITO, polythiophene (poly(ethylenedioxy)thiophene which will be hereinafter abbreviated as PEDOT), polyphenylene vinylene (hereinafter abbreviated as PPV) or polyfluorene. In that case, these materials and the auxiliary electrodes are provided together or laminated.

Next, description will be given to a material constituting the photoelectric converting region 34 in the organic photoelectric converting unit 30.

For the electron donating material 350, there are suitably used polymers such as phenylenevinylene, for example, methoxy-ethylhexoxy-polyphenylenevinylene (MEH-PPV), fluorine, carbazole, indole, pyrene, pyrrole, picoline, thiophene, acetylene and diacetylene, derivatives thereof, and these organic polymer materials.

Moreover, these polymers are not restricted but it is also possible to use a polyphyrin compound such as porphin, tetraphenylporphin copper, phthalocyanine, copper phthalocyanine or titanium phthalocyanine oxide, aromatic tertiary amine such as 1,1′-bis[4-(di-P-tolylamino)phenyl]cyclohexane, 4,4′,4″-trimethyltriphenylamine, N,N,N′,N′-tetrakis(P-tolyl)-P-phenylenediamine, 1-(N,N-di-P-tolylamino)naphthalene, 4,4′-bis(dimethylamino)-2-2′-dimethyltriphenyl methane, N,N,N′,N′-tetraphenyl-4,4′-diaminobiphenyl, N,N′-diphenyl-N,N′-di-m-tolyl-4,4′-diaminophenyl, or N-phenylcarbozole, a stilbene compound such as 4-di-P-tolylamino stilben, 4-(di-P-tolylamino)-4′-[4-(di-P-tolylamino) styryl]stilbene, a triazole derivative, an oxadizazole derivative, an imidazole derivative, a polyarylalkane derivative, a pyrazoline derivative, a pyrazolone derivative, a phenylenediamine derivative, an anilamine derivative, an amino substituted chalcone derivative, an oxazole derivative, a styrylanthracene derivative, a fluorenon derivative, a hydrazone derivative, a silazane derivative, a polysilane type aniline type copolymer, polymer oligomer, a styrylamine compound, an aromatic dimethylidine type compound, or poly-3-methylthiophene.

As in the relationship between the electron donating organic material 350a and the electron donating organic material 350b, materials having different wavelength properties to be absorbed are preferably selected properly from the materials described above. In this case, different types of materials may be used in combination or the same type of materials may be regulated to have different wavelength properties to be absorbed. For example, the organic polymer materials can be chemically modified to regulate the absorption wavelength properties.

For the electron accepting material 360, moreover, it is possible to use electron accepting organic materials such as fullerenes and carbon nano tubes including C60 and C70, their derivatives, an oxadiazole derivative, for example, 1,3-bis(4-tert-butylphenyl-1,3,4-oxadiazolyl)phenylene (OXD-7), an anthraquinodimethane derivative or a diphenylquinone derivative.

In order to flatten an interface between the electrode (the anode 32 or the cathode 33) and the photoelectric converting region 34, moreover, a buffer layer may be provided between the electrode and the photoelectric converting region 34. For the buffer layer, PEDOT is used.

As a fabricating method of fabricating the organic photoelectric converting unit 30 by using the material having each structure described above, it is also possible to use various vacuum processes such as a vacuum deposition method and a sputtering method or wet processes such as a spin coating method and a dipping method. It is possible to optionally select the process adapted to a material and structure to be used.

Next, description will be given to the photoconductive unit to be the light receiving section 3. An electrode to be used is the same as that in the organic photoelectric converting unit 30. It is possible to use any photoconductive material for generating a carrier to contribute to electrical conduction in a light irradiation. For example, polyvinylcarbazole can be used. Moreover, a combination of an optical carrier generating material and a carrier transporting material has no problem. In this case, a phthalocyanine derivative, a perylene derivative, an azo type pigment and a squarylium salt can be used for the optical carrier generating material. For the carrier transporting material, moreover, it is possible to suitably use an oxadiazole derivative, a pyrazoline derivative, a hydrozone derivative, an arylamine derivative, and furthermore, a stilbene derivative.

Also in embodiments which will be described below, it is possible to variously combine and use the light emitting section 2 constituted by various organic electroluminescence units 20, the light receiving section 3 constituted by various organic photoelectric converting units 30 and photoconductive units, these materials, and furthermore, the material of the substrate 1 in the first embodiment described above.

### Second Embodiment

FIGS. 14 and 15 are schematic sectional views showing the main parts of an information reading unit according to a second embodiment of the invention.

While there has been shown the structure in which the light receiving section 3 and the light emitting section 2 are directly provided on the substrate 1 in FIGS. 1 to 3 in the first embodiment, it is not restricted but various modifications can be made. More specifically, the light receiving section 3 and the light emitting section 2 may be separately fabricated and superposed on the substrate 1 as shown in FIG. 14.

Furthermore, the substrate 1, the light emitting section 2 and the light receiving section 3 may have the relationship of arrangement shown in FIG. 15.

### Third Embodiment

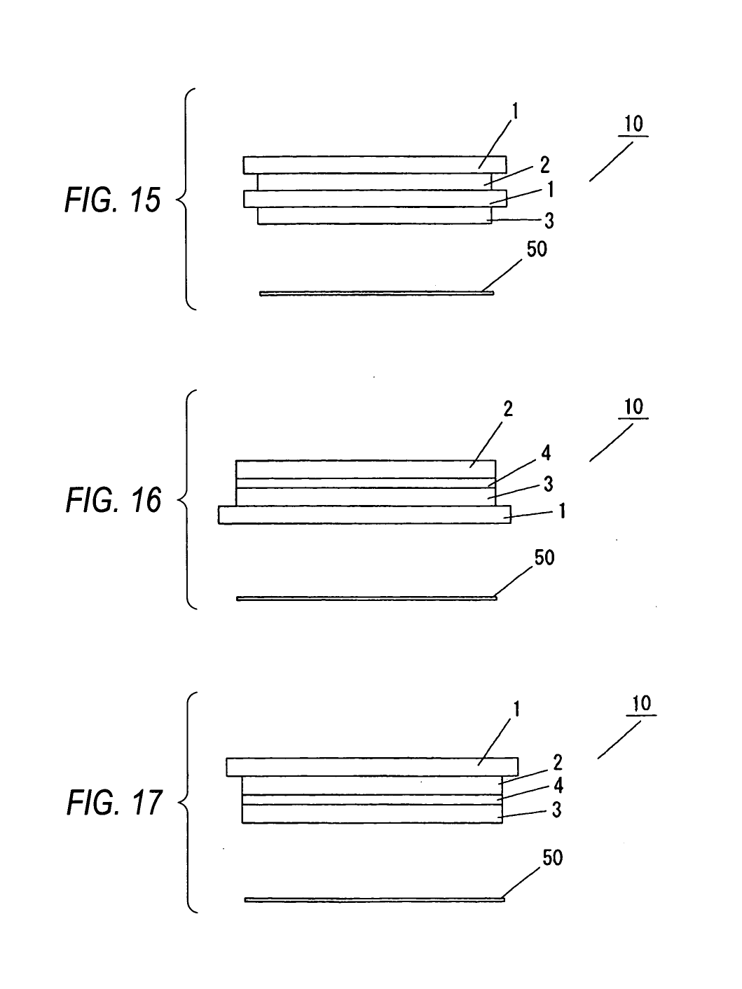

FIGS. 16, 17 and 18 are schematic sectional views showing the main parts of an information reading unit according to a third embodiment of the invention. 4 denotes an electric insulating layer.

The electric insulating layer 4 may be provided between the light receiving section 3 and the light emitting section 2 also in the case in which they are formed on the same substrate 1 as shown in FIG. 16. The electric insulating layer 4 has a light transmitting property in at least the light emitting region of the light emitting section 2 corresponding to the light receiving region of the light receiving section 3.

Furthermore, the substrate 1, the light emitting section 2 and the light receiving section 3 may have the relationship of arrangement shown in FIG. 17.

Description will be given to the case in which the organic electroluminescence unit 20 shown in FIG. 5 is used as the light emitting section 2 and the organic photoelectric converting unit 30 shown in FIG. 8 is used as the light receiving section 3 in the structure of an information reading unit 10 shown in FIG. 16.

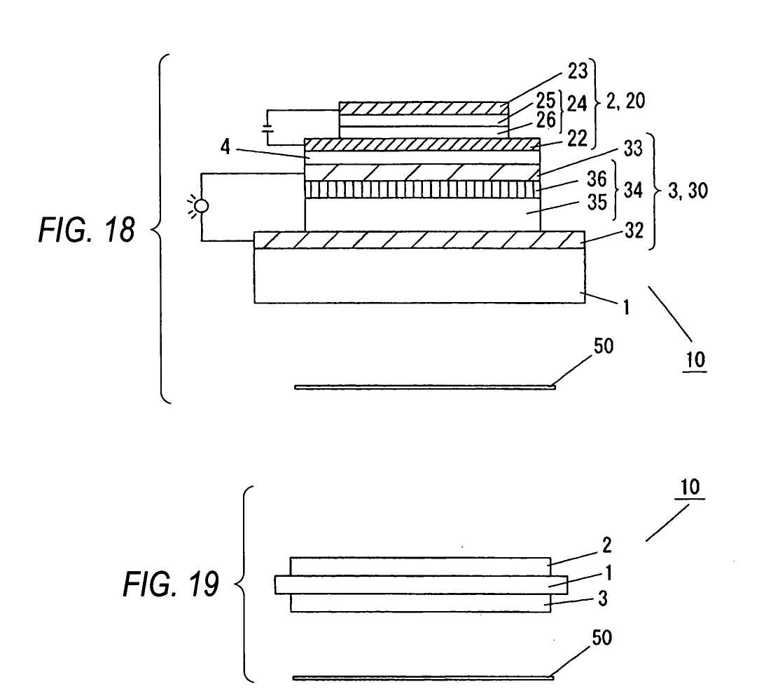

As shown in FIG. 18, a light incident on the organic photoelectric converting unit 30 to be the light receiving section 3 is the sum of a direct light emitted from the light emitting section 2 (the organic electroluminescence unit 20) and a light reflected from an object 50, and is previously offset by the direct light. Since the organic photoelectric converting unit 30 to be the light receiving section 3 used in the third embodiment has a very great dynamic range, information about the object can be sufficiently fetched. In a preferable configuration, accordingly, the organic photoelectric converting unit 30 is used for the light receiving section 3.

Moreover, a thickness and a size can be reduced, and furthermore, a variation in an illuminance on the object can be reduced by a planar light emission having a high luminance, the formation can be carried out by an applying method and a cost can also be reduced. In a preferable configuration, therefore, the organic electroluminescence unit 20 is used for the light emitting section 2.

Moreover, the organic electroluminescence unit 20 and the organic photoelectric converting unit 30 can easily be laminated through the electric insulating layer 4.

The structures of the organic electroluminescence unit 20 and the organic photoelectric converting unit 30 used in the third embodiment are taken as an example, and it is apparent that the organic electroluminescence unit 20 and organic photoelectric converting unit 30 having other structures may be variously combined and used.

While the case in which the light receiving section 3 serves as the organic photoelectric converting unit 30 has been described in the third embodiment, moreover, the same function can be fulfilled even if a photoconductive unit is instead used.

### Fourth Embodiment

As shown in FIG. 19, furthermore, it is also possible to employ a structure in which a light receiving section 3 and a light emitting section 2 are separately formed on both sides of a substrate 1. FIG. 19 is a schematic sectional view showing the main parts of an information reading unit according to a fourth embodiment of the invention. Moreover, the structure of an information reading unit 10 according to the fourth embodiment of the invention is suitable because the substrate 1 can be shared in the case in which the organic electroluminescence unit 20 is used as the light emitting section 2 and the organic photoelectric converting unit 30 is used as the light receiving section 3 as described in the first embodiment.

### Fifth Embodiment

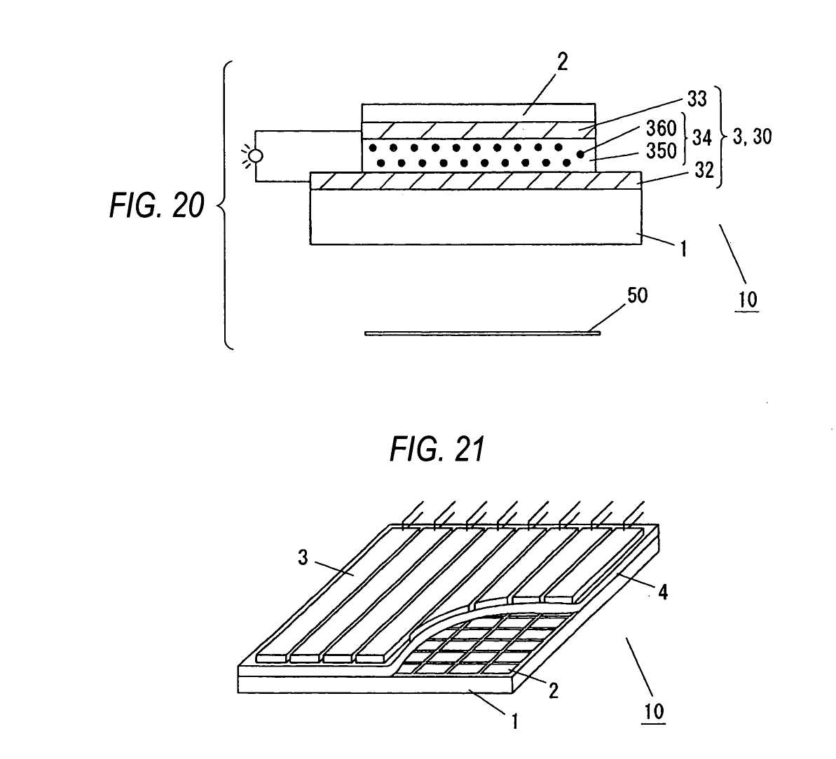

FIG. 20 is a sectional view showing the main parts of an information reading unit according to a fifth embodiment of the invention.

In the fifth embodiment, the organic photoelectric converting unit 30 shown in FIG. 11 is used as the light receiving section 3.

For example, it is supposed that polyphenylenevinylene (PPV) is used as an electron donating organic material 350 and fullerene is used as an electron accepting material 360. An electron moving speed between the polyphenylenevinylene (PPV) and the fullerene is very high and they are material types in which attention has been greatly paid to an application to the photoelectric converting unit. Also in a simple structure in which these two materials are mixed and applied by spin coating, particularly, a comparatively high light-electric conversion efficiency can be obtained. Therefore, a study of the implementation of an organic solar battery at a low cost has vigorously been made. By using the same material type and engineering method for the application of a light receiving unit, it is possible to form the light receiving unit having a high performance at a low cost. The electron accepting material 360 is not restricted to the fullerene but a derivative thereof, and furthermore, a carbon nano tube and a derivative thereof have no problem.

### Sixth Embodiment

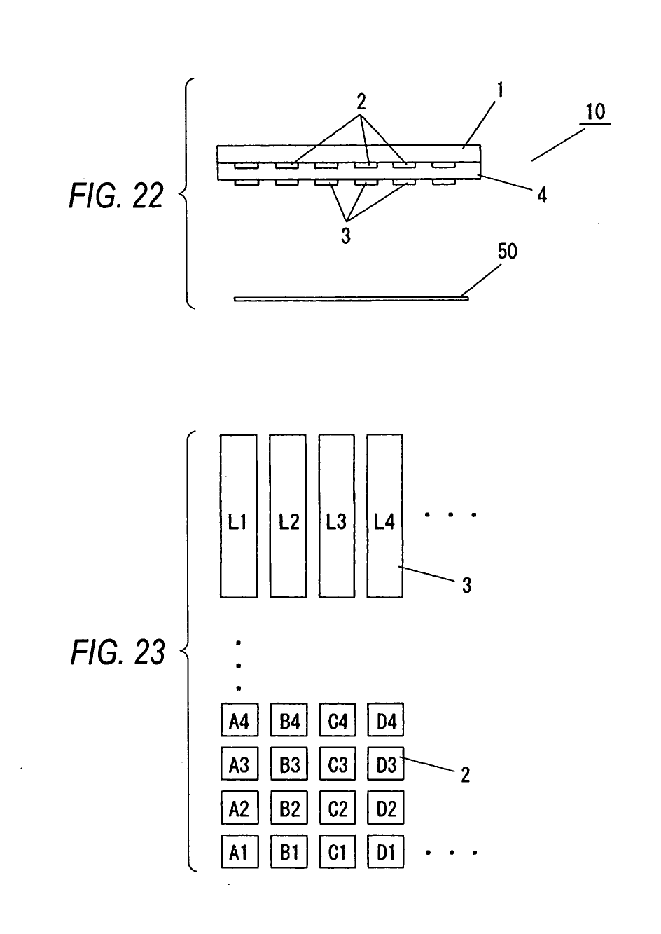

FIG. 21 is a perspective view showing the main parts of an information reading unit according to a sixth embodiment of the invention, and FIG. 22 is a sectional view showing the main parts of the information reading unit according to the sixth embodiment of the invention. FIG. 21 shows a state in which an object is seen in the direction of arrangement (a reading surface).

In the sixth embodiment, a light emitting unit 2 is arranged in a matrix. Each light emitting unit 2 can individually irradiate a light and the reflection of each light over an object surface is received by a light receiving section 3 in the same manner as in the first embodiment.

An irradiation on an object by the light emitting section 2 and a receipt of a reflected light by the light receiving section 3 will be described in more detail with reference to FIG. 23. FIG. 23 is a view for explaining the relationship between the individual light emitting sections and light receiving sections in the information reading unit according to the sixth embodiment of the invention. In FIG. 23, A1 to A4, B1 to B4, C1 to C4, and D1 to D4 denote individual light emitting sections, and L1 to L4 denote light emitting sections corresponding to individual light receiving sections.

Lights emitted from the light emitting sections A1 to A4 are received by the light receiving section L1. Similarly, L2 for B1 to B4, L3 for C1 to C4, and L4 for D1 to D4 are corresponding light receiving sections, respectively. First of all, the light emitting section A1 emits a light, and the same light is reflected by an object and is then converted into electric information by the light receiving section L1. Subsequently, A2, A3 and A4 sequentially emit lights, and reflected lights are received by L1 and are converted into electric information respectively. Similarly, B, C and D sequentially repeat the emission and receipt of lights.

Thus, information about the object is converted into the electric information. In the sixth embodiment, the light emitting sections 2 are arranged in a matrix and a plurality of light receiving sections 3 is arranged to obtain the information. In addition, it is also possible to use a method in which the light receiving section 3 is constituted by only one planar light receiving section and the light emitting section 2 is sequentially driven to obtain information, or a method in which the light emitting section 2 is formed by one planar light source or a plurality of line-shaped light sources and the light receiving section 3 is arranged in a matrix, which has no problem.

### Seventh Embodiment

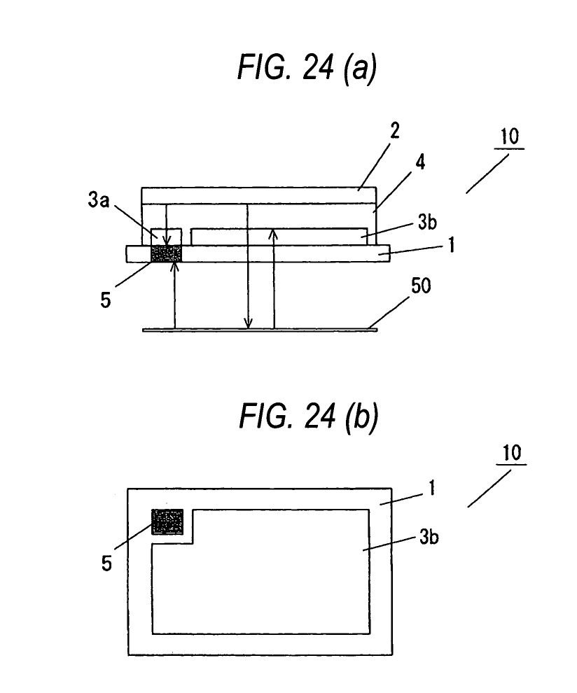

FIG. 24(a) is a sectional view showing the main parts of an information reading unit according to a seventh embodiment of the invention, and FIG. 24(b) is a plan view showing the main parts of the information reading unit according to the seventh embodiment of the invention. In FIG. 24, 3a denotes a light receiving section for reference and 3b denotes a light receiving section for reading. 5 denotes a light shielding section. FIG. 24(b) is a view showing a state in which an object 50 is seen in a direction of arrangement (a reading surface).

In the seventh embodiment, the light receiving section is divided into two parts, that is, the light receiving section 3a for reference and the light receiving section 3b for reading. The light receiving section 3a for reference is provided with the light shielding section 5 for shielding a reflected light.

In an information reading unit 10, a light irradiated from a light emitting section 2 can be received by both the light receiving section 3a for reference and the light receiving section 3b for reading. A light reflected by the object cannot be received by the light receiving section 3a for reference but can be received by only the light receiving section 3b for reading because the light shielding section 5 is present. Therefore, it is possible to calculate the ratio of the direct light to the reflected light in the light receiving section 3b for reading based on the light received by the light receiving section 3a for reference. Consequently, the SN ratio of object information can be increased very greatly.

While there has been described the example in which the light shielding section 5 is buried in the substrate 1 in the seventh embodiment, the place in which the light shielding section 5 is to be provided is not restricted thereto. It is preferable to employ a structure in which the light reflected by the object 50 is not incident on the light receiving section 3a for reference. The light shielding section 5 may be provided between the substrate 1 and the light receiving section 3a for reference or may be formed on a reverse surface to a surface of the substrate 1 in which the light receiving section 3a for reference is provided. Although the light shielding section 5 can preferably shield a light reflected from an object, moreover, it is desirable to use such a material and structure that a direct light is absorbed and the light reflected by the light shielding section 5 is not returned to the light receiving section 3a for reference.

While the sizes of the light receiving section 3a for reference and the light receiving section 3b for reading are not particularly restricted, furthermore, it is desirable that the area of the light receiving section 3a for reference should be 10% or less of the area of the light receiving section 3b for reading in order not to reduce a resolution.

### Eighth Embodiment

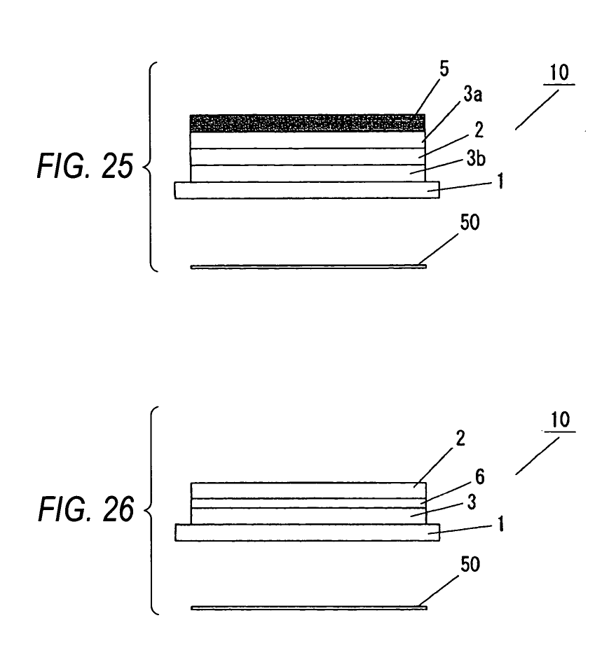

FIG. 25 is a sectional view showing the main parts of an information reading unit according to an eighth embodiment of the invention.

In the eighth embodiment, a light emitting section 2 is interposed between a light receiving section 3a for reference and a light receiving section 3b for reading. A part of a light irradiated from the light emitting section 2 passes through the light receiving section 3b for reading and reaches an object 50, and is reflected by a surface and is returned to the light receiving section 3b for reading again. On the other hand, if a light source capable of irradiating a light in all directions, that is, the organic electroluminescence unit 20 is used, a light emitted from the light emitting section 2 is also irradiated in an opposite direction to the object 50 and is received by the light receiving section 3a for reference so that the ratio of a direct light to a reflected light in the light receiving section 3b for reading can be calculated. Consequently, the SN ratio of object information can be increased very greatly. Desirably, a light shielding section 5 in the eighth embodiment also has such a material and structure that a direct light is absorbed and a reflected light is not returned to the light receiving section 3a for reference.

### Ninth Embodiment

FIG. 26 is a sectional view showing the main parts of an information reading unit according to a ninth embodiment of the invention. 6 denotes a polarizer.

In the ninth embodiment, the polarizer 6 is provided between a light emitting section 2 and a light receiving section 3, and furthermore, the light receiving section 3 has a polarizing absorption property. Description will be given to the case in which an organic photoelectric converting unit 30 is used as the light receiving section 3.

A light emitted from the light emitting section 2 passes through the polarizer 6 and is changed to a polarized light. If a polarizing plane for the irradiated light is different from a polarizing plane of the organic photoelectric converting unit 30 which can carry out an absorption, it can pass through the organic photoelectric converting unit 30 without a light absorption. The polarized light reaching an object is relaxed in a reflection on the surface of an object 50 and is then returned to the light receiving section 3 again, and is absorbed for the first time. Thus, a polarizing absorption property is given to the light receiving section 3 so that only the intensity of a reflected light can be received without the influence of a direct light. Consequently, the SN ratio of object information can be increased very greatly.

In the light receiving section 3 used in the ninth embodiment, for example, a polymer material to be an electron donating material absorbs a light to bring an excitation state, thereby generating a carrier. If the excitation state is not brought, that is, the light is not absorbed, therefore, light information cannot be converted to electric information. For this reason, it is necessary to use a method of giving a polarizing absorption property to the light receiving section 3 so as not to cause the electron donating material to absorb a light. For this method, the orientation of a constitutive material by rubbing or drawing is effective.

### Tenth Embodiment

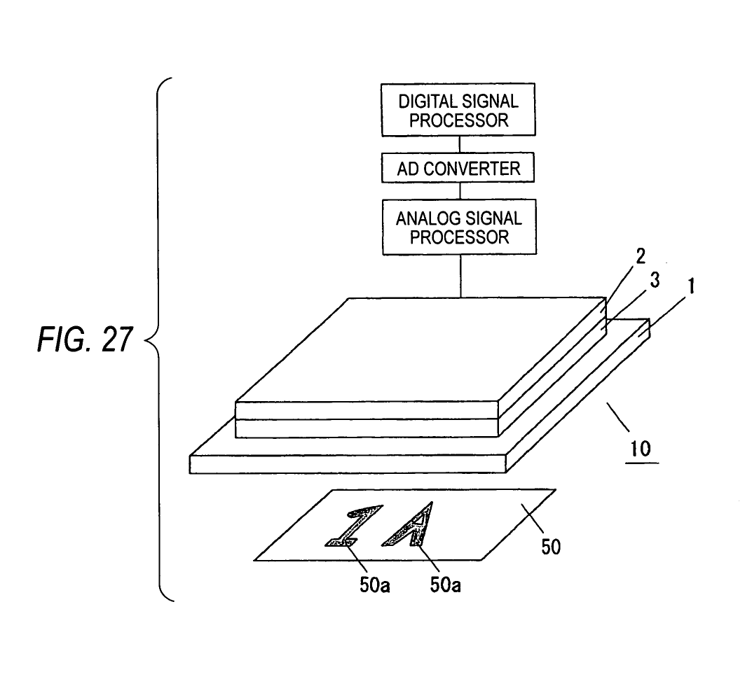

FIG. 27 is a view showing the structure of an information reading device according to a tenth embodiment of the invention.

In the information reading device according to the tenth embodiment, an information reading unit 10 comprising a substrate 1, a light emitting section 2 and a light receiving section 3 is connected to an analog signal processing section, an AD converter and a digital signal processing section. Consequently, electric information obtained by the light receiving section 3 can be converted to a digital signal so that information 50a of an object 50 can be obtained.

For the information reading device according to the tenth embodiment, the information reading unit 10 according to any of the first to ninth embodiments may be used.

### Eleventh Embodiment

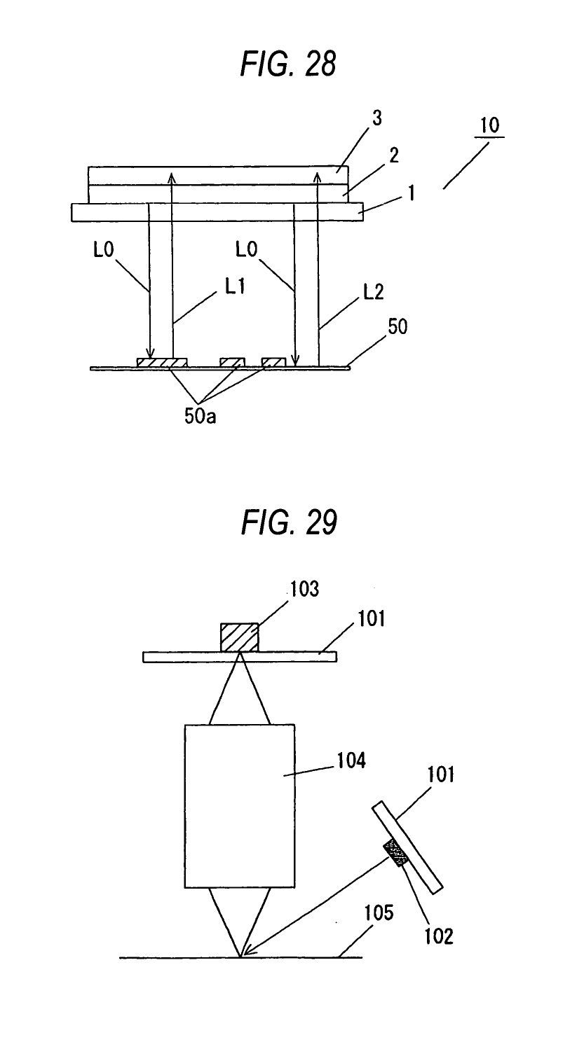

FIG. 28 is a sectional view showing the main parts of an information reading unit according to an eleventh embodiment of the invention. In the eleventh embodiment, a light emitting section 2 has a light transmitting property. A light discharged from the light emitting section 2 passes through a substrate 1 and irradiates a light on an object 50 as shown in a beam L0. The irradiated light is reflected by the object 50. At this time, the intensity of the reflected light is varied depending on the presence of information 50a over the object 50. Description will be given on the assumption that the reflectance of the irradiated light in the information 50a is lower than that in other regions (the absorption of the irradiated light in the information 50a is greater than that in other regions on the object 50). The light reflected by the information 50a passes through the substrate 1 and the light emitting section 2 and is incident on a light receiving section 3 as shown in the beam L1. Moreover, the light reflected in a region in which the information 50a is not present passes through the substrate 1 and the light emitting section 2 and is incident on the light receiving section 3 as shown in a beam L2. When these reflected lights are received, a current corresponding to each of the reflected lights flows to a photoelectric converting unit constituting the light receiving section 3. At this time, the light reflected by the information 50a is weak and the current is smaller than a current generated by the light reflected in the other regions. In the light receiving section 3, accordingly, a difference in the intensity of the reflected light which is made by the presence of the information 50a in the object 50 can be output as a difference in the current corresponding thereto, and the presence of the information 50a, that is, the information recorded on the object 50 can be read.

Thus, the light emitting section 2 has a light transmitting property, and the light emitting section 2 and the light receiving section 3 have at least regions which are superposed on the same optical axis, that is, the light receiving region of the light receiving section 3 is superposed on the light emitting region of the light emitting section 2 in the direction of the optical axis. Consequently, a size and a thickness can be reduced.

However, the light emitting section 2 has a light transmitting property. Therefore, the light is irradiated on both the object 50 side and the light receiving section 3 side so that the utilization efficiency of a light is reduced. Consequently, it is preferable to employ the structure in which the light receiving section 3 has a light transmitting property as described in the first to tenth embodiments.

### Twelfth Embodiment

In an information reading sensor (an organic information reading sensor) using an organic photoelectric converting unit in a light receiving section, the information reading sensor is applicable for facsimile machines, copying machines, scanners or digital cameras, an organic material is formed over a whole surface without patterning and is not separated every light receiving section because the carrier mobility of an organic material is low and a carrier leakage between adjacent light receiving sections can be disregarded, and a cost is to be reduced in many cases.

In such a structure that the organic material is linked between the adjacent light receiving sections, there is no problem in the case in which the resolution of information to be read is low and an interval between the light receiving sections is great. In the case in which the resolution is raised and an increase in fineness is required, however, there is a problem in that the influence of a stray light leaking out through an organic material is increased, resulting in a deterioration in reading quality.

In order to solve the problem, it can be proposed that a non-translucent insulator is provided between the light receiving sections.

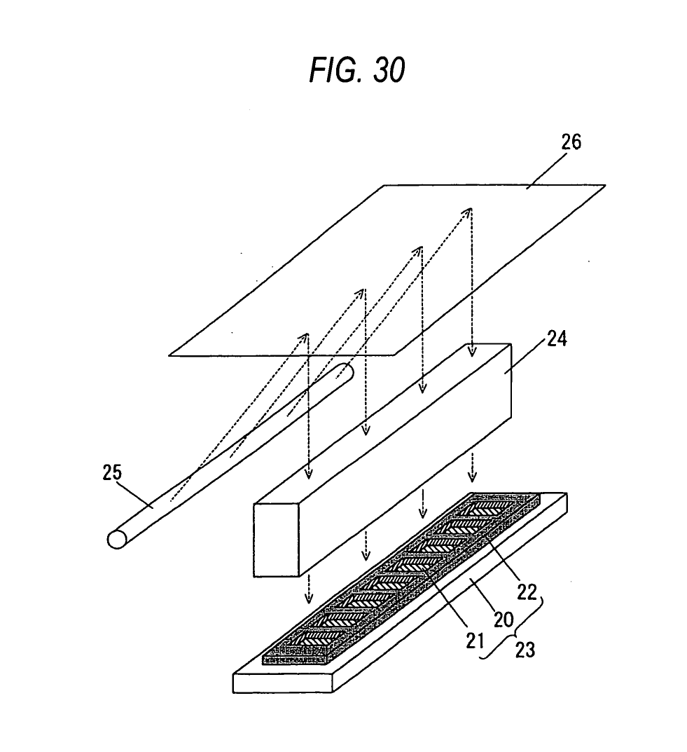

FIG. 30 is a perspective view showing an organic information reading module according to a twelfth embodiment of the invention.

As shown in FIG. 30, the organic information reading module includes an organic information reading sensor 23 having a non-translucent insulator 22 provided between a plurality of light receiving sections 21 formed on a substrate 20, a lens system 24 such as a SELFOC lens, and furthermore, a light source section 25.

A light emitted from the light source section 25 is reflected by a sample such as a manuscript 26 and is incident on the light receiving section 21 through the lens system 24, and the organic information reading sensor 23 converts the incident light into an electric signal and the electric signal is fetched to an external circuit so that information is read.

In that case, it is possible to implement the read of information of high quality in which a stray light is considerably suppressed by isolating the light receiving sections 21 constituting the organic information reading sensor 23 from each other through the non-translucent insulator 22.

Thus, the organic information reading sensor 23 according to the embodiment has the substrate 20 for supporting the light receiving section 21, the light receiving section 21 for converting a light signal into an electric signal, and furthermore, the non-translucent insulator 22 for separating the light receiving section 21.

The substrate 20 may be formed by any material which can support the light receiving section 21, and it is possible to use various polymer materials such as glass, polyethylene terephthalate, polycarbonate, polymethyl methacrylate, polyether sulfone, polyvinyl fluoride, polypropylene, polyethylene, polyacrylate, amorphous polyolefin and fluororesin, and furthermore, various metal materials including a silicon wafer.

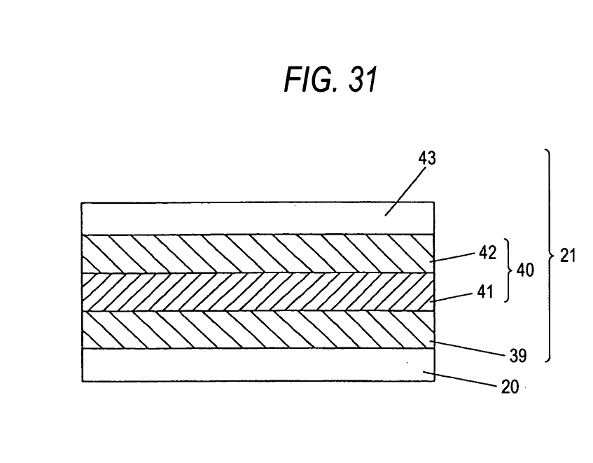

The light receiving section 21 is constituted by an anode 39, a photoelectric converting region 40, an electron donating layer 41 formed by an electron donating material, an electron accepting layer 42 formed by an electron accepting material, and a cathode 43 on the substrate 20 as shown in FIG. 31.

The anode 39 constituted by a transparent conductive film such as ITO (Indium-Tin Oxide) is formed on the light transmitting substrate 20 such as glass by sputtering or resistance heating evaporation, the photoelectric converting region 40 provided with the electron donating layer 41 and the electron accepting layer 42 by the resistance heating evaporation respectively is formed on the anode 39, and the cathode 43 formed of a metal is provided thereon by the resistance heating evaporation.

When a light is irradiated on an organic photoelectric converting unit having the structure described above, a light absorption is caused in the photoelectric converting region 40 so that an exciton is formed. Subsequently, a carrier is separated, an electron is moved to the cathode 43 through the electron accepting layer 42, and a hole is moved to the anode 39 through the electron donating layer 41. Consequently, an electromotive force is generated between both electrodes and an external circuit is connected so that an electric signal can be fetched.

For the electron donating material to be the constituent of the electron donating layer 41, there are used a polymer having, as a repetitive unit, a derivative such as phenylenevinylene, fluorene, carbazole, indole, pyrene, pyrrole, picoline, thiophene, acetylene and diacetylene, a copolymer with other monomers, and a group of polymer materials referred to as dendrimer. Moreover, the material is not restricted to a polymer but it is also possible to use, for example, a polyphyrin compound such as porphin, tetraphenylporphin copper, phthalocyanine, copper phthalocyanine or titanium phthalocyanine oxide, aromatic tertiary amine such as 1,1-bis[4-(di-P-tolylamino)phenyl]cyclohexane, 4,4′,4″-trimethyltriphenylamine, N,N,N′,N′-tetrakis(P-tolyl)-P-phenylenediamine, 1-(N,N-di-P-tolylamino)naphthalene, 4,4′-bis(dimethylamino)-2-2′-dimethyltriphenylmethane, N,N,N′,N′-tetraphenyl-4,4′-diaminobiphenyl, N,N′-diphenyl-N,N′-di-m-tolyl-4,4′-diaminobiphenyl, or N-phenylcarbazole, a stilbene compound such as 4-di-P-tolylamino stilbene, 4-(di-P-tolylamino)-4′-[4-(di-P-tolylamino) styryl]stilbene, a triazole derivative, an oxadizazole derivative, an imidazole derivative, a polyarylalkane derivative, a pyrazoline derivative, a pyrazolone derivative, a phenylenediamine derivative, an anilamine derivative, an amino substituted chalcone derivative, an oxazole derivative, a styrylanthracene derivative, a fluorenon derivative, a hydrazone derivative, a silazane derivative, a polysilane type aniline type copolymer, polymer oligomer, a styrylamine compound, an aromatic dimethylidine type compound, or poly-3-methylthiophene.

For the electron accepting material to be the constituent of the electron accepting layer 42, moreover, it is possible to use an oxadiazole derivative such as 1,3-bis(4-tert-butylphenyl-1,3,4-oxadiazolyl)phenylene (OXD-7), an anthraquinodimethane derivative, and a diphenylquinone derivative.

A characteristic required for a material to be used for the non-translucent insulator 22, it is important that patterning can be carried out to have an optional shape in addition to no passage of an electricity and a light. A material satisfying the characteristic includes various polymer materials such as a photocuring resin and metal oxides such as chromium oxide.

ITO, ATO (SnO2 doped with Sb) or AZO (ZnO doped with Al) is used for the anode 39, and furthermore, a metal material such as Al, Ag or Au is usually used for the cathode 43.

Moreover, there is suitably used the structure of an element in which a polymer material such as PEDOT:PSS (a mixture of polythiophene and polystyrenesulfonic acid), a metal fluoride including LiF or an oxide is introduced as a buffer layer between each electrode and the photoelectric converting region 40 if necessary.

Furthermore, it is also possible to give a light transmitting property by constituting both the anode 39 and the cathode 43 with a light transmitting material, for example, a thin metal film such as ITO, ATO, AZO, Al, Ag or Au. Consequently, it is possible to provide the light receiving section 21 having the light transmitting property.

The organic information reading sensor 23 shown in FIG. 30 is an example of a line sensor in which the light receiving section 21 is provided one-dimensionally. There is no problem even if the sensor is used as an area sensor with a two-dimensional arrangement, and furthermore, the area sensor is bent for use.

Further description will be given to a variation in the structure of the non-translucent insulator 22 in the organic information reading sensor 23.

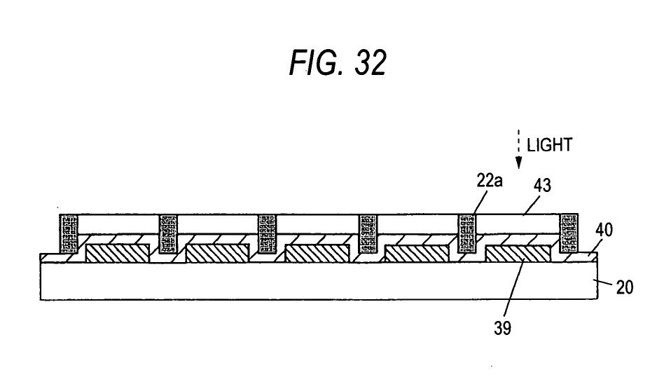

FIG. 32 is a sectional view showing the main part of the organic information reading sensor according to the twelfth embodiment of the invention.

In FIG. 32, the light receiving section 21 is constituted by the anode 39, the photoelectric converting region 40 and the cathode 43 on the substrate 20.

The organic information reading sensor 23 shown in FIG. 32 is different from that in the conventional art in that a non-translucent insulator 22a is provided between the light receiving sections 21.

The non-translucent insulator 22a is provided on the level with the cathode 43 over the photoelectric converting region 40 as shown in FIG. 32.

The propagation of a light between the light receiving sections 21 is considerably limited by the non-translucent insulator 22a and a light incident on any of the light receiving sections 21 is absorbed by only the same light receiving section 21 and is converted into an electric signal.

Thus, it is possible to suppress the propagation of a light between the light receiving sections 21 to generate a stray light. Consequently, it is possible to provide the organic information reading sensor 23 having high quality and resolution.

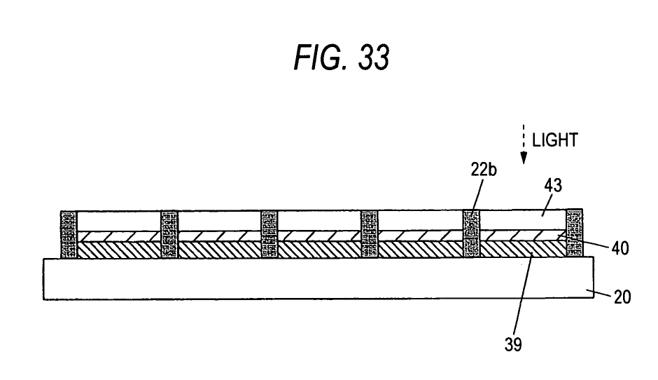

FIG. 33 is a sectional view showing the main part of the organic information reading sensor according to the twelfth embodiment of the invention.

In FIG. 33, each light receiving section 21 is constituted by the anode 39, the photoelectric converting region 40 and the cathode 43 on the substrate 20.

The organic information reading sensor 23 shown in FIG. 33 is different from that shown in FIG. 32 in that the light receiving sections 21 are isolated perfectly from each other through a non-translucent insulator 22b.

The perfect isolation indicates that the anodes 39 of the adjacent light receiving sections 21, the photoelectric converting regions 40 and the cathodes 43 are not connected to each other on the same plane.

Consequently, a light incident on any of the light receiving sections 21 is absorbed by only the same light receiving section 21 and is converted into an electric signal, and it is possible to suppress the propagation of a light in the photoelectric converting region 40, each of the electrodes or their interface regions to generate a stray light more perfectly as compared with that shown in FIG. 32.

Although the wiring of each electrode is important when the light receiving sections 21 are to be separated from each other, the separation can be carried out by using a TFT (Thin Film Transistor) substrate capable of separately fetching the signal of the light receiving section 21, for example.

Moreover, it is possible to use any material of the non-translucent insulator 22b which can shield a light and has an insulating property, and oxides including Cr2O3 and various polymer materials are suitably used.

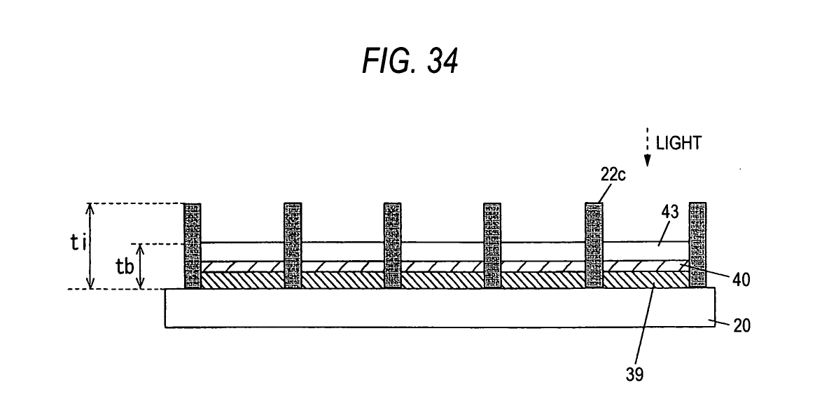

FIG. 34 is a sectional view showing the main part of an organic information reading sensor according to the twelfth embodiment of the invention.

In FIG. 34, each light receiving section 21 is constituted by the anode 39, the photoelectric converting region 40 and the cathode 43 on the substrate 20.

The organic information reading sensor 23 shown in FIG. 34 is different from that shown in FIGS. 32 and 33 in that a thickness ti of a non-translucent insulator 22c is greater than a thickness td of the light receiving section 21.

More specifically, in the organic information reading sensor 23 shown in FIG. 34, the non-translucent insulator 22c is protruded upward from the light receiving section 21. By such a structure, it is possible to shield the oblique component of a light incident on the light receiving section 21. Thus, it is possible to read information with high resolution.

According to the above-mentioned embodiment, the relationship between the thickness ti and the thickness td is defined as ti>td. However, it should be understand the relationship ti>2td is desirable. Moreover, the relationship ti>5td is further desirable.

Furthermore, the non-translucent insulator 22c also serves as the protecting member of the light receiving section 21. Also in the case in which the organic information reading sensor 23 directly comes in contact with a sample, for example, the light receiving section 21 is protected by the non-translucent insulator 22c and a breakdown can be suppressed.

While the organic information reading sensor 23 shown in FIG. 34 has such a structure that the light receiving section 21 is perfectly shielded in the same manner as in FIG. 33, it is also possible to employ a structure in which the photoelectric converting region 40 or the anode 39 is not shielded as shown in FIG. 32.

### Thirteenth Embodiment

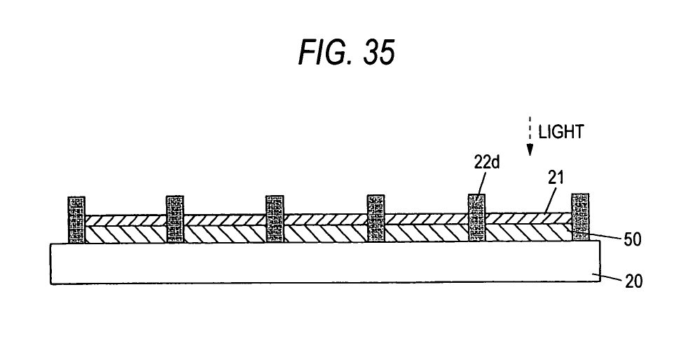

FIG. 35 is a sectional view showing the main part of an organic information reading sensor according to a thirteenth embodiment of the invention.

In FIG. 35, 20 denotes a substrate, 21 denotes a light receiving section, 22d denotes a non-translucent insulator, and 50 denotes a light emitting section.

In an information reading sensor 23 shown in FIG. 35, a plurality of light receiving sections 21 separated by the non-translucent insulator 22d has individual light emitting sections 50 respectively, and furthermore, the light emitting section 50 is formed between the substrate 20 and the light receiving section 21, and the light receiving section 21 and the light emitting section 50 are laminated.

As shown in FIG. 35, the light receiving section 21 and the light emitting section 50 are laminated. Consequently, a space for obliquely irradiating a light on a sample such as a manuscript as shown in FIG. 30 is not required so that the size and space of an information reading device can be reduced.

It is possible to employ any arrangement relationship between the light emitting section 50 and the light receiving section 21 which can effectively irradiate and receive a light. For example, it is also possible to employ a configuration in which the substrate 20, the light receiving section 21 and the light emitting section 50 are laminated in order in addition to the configuration in which the substrate 20, the light emitting section 50 and the light receiving section 21 are laminated in order as shown in FIG. 35.

Furthermore, it is also possible to employ various lamination structures described in the First Embodiment to the Eleventh Embodiment.

It is also possible to propose a configuration in which the light receiving section 21 and the light emitting section 50 are neither arranged on the same plane or almost the same plane nor laminated perfectly but are laminated with a shift in that the light receiving sections 21 have the individual light emitting sections 50 respectively.

In this case, a shift is generated between the direction of the irradiation of a light from the light emitting section 50 and the direction of the incidence of the light on the light receiving section 21. For this reason, more space is required as the information reading device as compared with the case in which the perfect lamination is carried out as shown in FIG. 35. However, it is possible to implement space saving more greatly than the structure shown in FIG. 6 in which the light source is provided separately.

While the description has been given to the configuration in which the light emitting section 50 is individually provided for the light receiving section 21, it is also possible to propose a configuration in which the single light emitting section 50 is provided or the light emitting section 50 is provided for some light receiving sections 21 in common.

For the arrangement and structure of the non-translucent insulator 22d, moreover, various structure patterns can be applied as shown in FIGS. 32 to 34 according to the twelfth embodiment.

### Fourteenth Embodiment

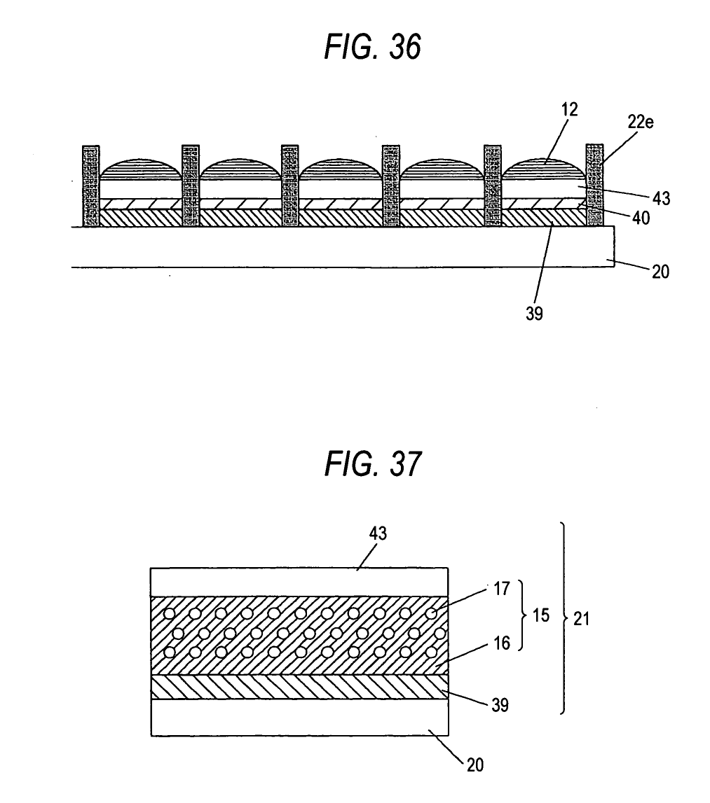

FIG. 36 is a sectional view showing the main part of an organic information reading sensor according to a fourteenth embodiment of the invention.

In FIG. 36, each light receiving section 21 is constituted by an anode 39, a photoelectric converting region 40 and a cathode 43 on a substrate 20.

In the organic information reading sensor shown in FIG. 36, the light receiving sections 21 have individual lens arrays 12 respectively, and have great focal depths and can carry out the read of information of high quality.

For the arrangement of the lens array 12, a technique for aligning the sheet-like lens array 12 on the light receiving section 21 and sticking them is suitably used. In addition, it is also possible to suitably use a method of forming the lens array 12 by applying a resin onto the light receiving section 21 surrounded by a non-translucent insulator 22e to be separated through the non-translucent insulator 22e.

By the formation of the individual lens arrays 12 on the light receiving sections 21, a lens system 24 such as an external SELFOC lens shown in FIG. 1 is not required. Consequently, it is possible to provide an information reading module of a perfect contact type which has a size and thickness reduced considerably.

By using the lens array 12 separated every light receiving section 21, it is possible to considerably improve a stray light in the lens array 12, thereby carrying out the read of information of high quality.

Since most of information reading modules of a perfect contact type according to the conventional art have no lens, focal depths are small. However, each pixel is provided with the lens array 12 separated through the non-translucent insulator 22e in the organic information reading sensor according to the embodiment. Therefore, it is possible to provide the information reading module of a perfect contact type which has a great focal depth.

For the arrangement and structure of the non-translucent insulator 22e, it is possible to apply various structure patterns as shown in FIGS. 32 to 34 according to the twelfth embodiment.

Furthermore, the invention can also be applied to a structure in which the light receiving section 21 has an individual light emitting section in the same manner as in the thirteenth embodiment.

Any method for forming a lens array can be employed if a lens can be formed after formation of the non-translucent insulator. Wet process such as ink jet method is preferable because it is easily to form a lens array.

### Fifteenth Embodiment

FIG. 37 is a sectional view showing the main part of an organic photoelectric converting unit according to a fifteenth embodiment of the invention.

In FIG. 37, a photoelectric converting region 15 is formed between an anode 39 and a cathode 43 on a substrate 20, and the photoelectric converting region 15 has at least one kind of electron donating organic material 16 between electrodes and an electron accepting material 17 containing fullerenes and/or carbon nano tubes.

Referring to the organic photoelectric converting unit using these materials, it is sufficient that a mixture of materials is applied and a light receiving section 21 can be formed more easily as compared with the case in which the electron donating organic material and the electron accepting material are laminated as shown in FIG. 31.

Therefore, it is possible to provide an organic information reading sensor and an information reading device in which a structure can be simplified and a cost can be reduced.

The structure of the photoelectric converting region 15 according to the embodiment can also be applied to any of the twelfth to fourteenth embodiments described above.

### Sixteenth Embodiment

Description will be given to a method of manufacturing an organic information reading sensor according to the invention.

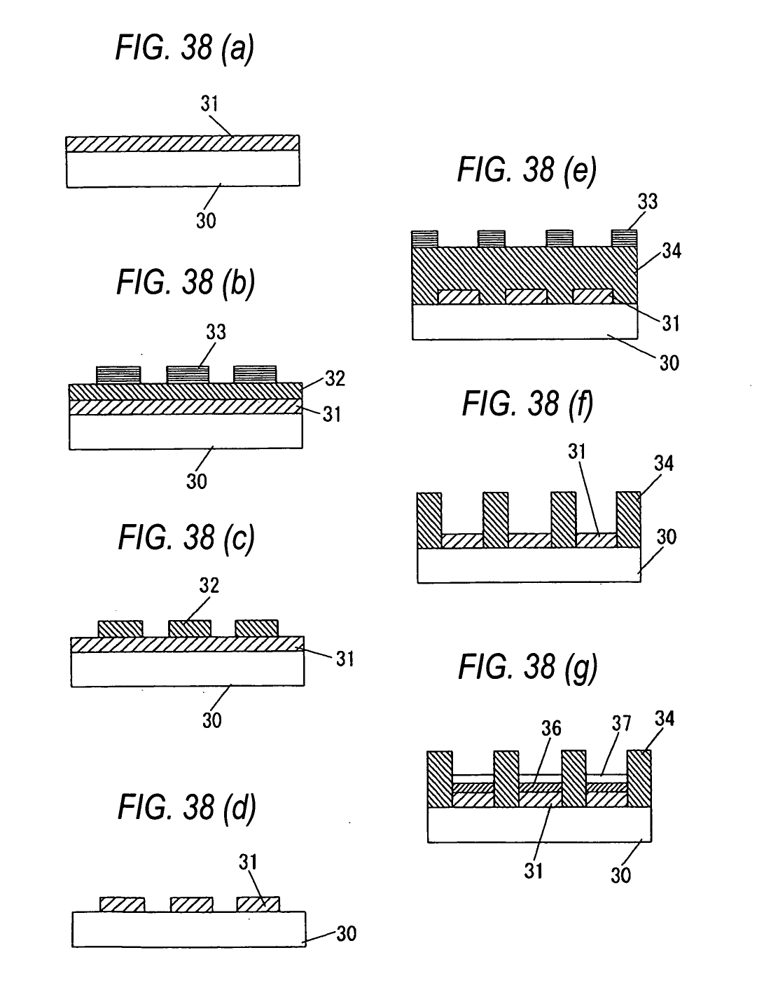

FIGS. 38(a) to 38(g) show a process for manufacturing an organic information reading sensor according to a sixteenth embodiment of the invention.

In FIGS. 38(a) to 38(g), first of all, an ITO film 31 is formed on a glass substrate 30 by sputtering (FIG. 38(a)). A resist film 32 is formed on the ITO film 31 by spin coating and a mask 33 is provided thereon (FIG. 38(b)).

Next, exposure is carried out through the mask 33 and development is then performed, and the resist film 32 is thereafter subjected to patterning to have a predetermined shape (FIG. 38(c)).

Subsequently, the ITO film 31 is subjected to etching to form an ITO electrode having a predetermined shape (FIG. 38(d)).

Then, a chromium oxide film 34 is formed on the glass substrate 30 by the sputtering, and furthermore, the resist film 32 is formed thereon and mask exposure and development are carried out in the same manner as the patterning of the ITO film 31. Thus, the resist film 32 is subjected to the patterning (FIG. 38(e)).

Furthermore, the chromium oxide film 34 is subjected to the etching by using the resist film 32 as the mask 33. Thus, a non-translucent insulator 35 is formed (FIG. 38(f)).

A photoelectric converting region 36 and an electrode 37 are provided, by using an ink jet method or a mask evaporation method, on the substrate thus formed (FIG. 38(g)). Consequently, it is possible to form an organic information reading sensor in which light receiving sections are separated through the non-translucent insulator 35.

As mentioned above, because the non-translucent insulator is formed before formation of the light receiving section, a process or materials for producing have little restriction. Therefore, the non-translucent insulator can be stably produced with any shape.

Moreover, the non-translucent insulator according to the invention can suppress a stray light and can carry out the read of information of high quality, and furthermore, has a great advantage in a process for manufacturing an organic information reading sensor.

For example, in the case in which approaching photoelectric converting pixels are to be formed by different materials in order to read color information, such patterning is generally carried out by properly painting the photoelectric converting regions by the ink jet method. If a resolution is high and an interval between the pixels is small, the material spreads to adjacent pixels so that the proper painting cannot be carried out well. For this reason, there is used a method of forming a wall referred to as a pixel forming layer by a photosensitive polymer material in order to suppress the spread of the material and leaving the applied material therein.

Moreover, the use of the pixel forming layer does not require patterning for an upper electrode to be formed on the photoelectric converting region. The non-translucent insulator according to the invention can also serve as the pixel forming layer and can easily carry out the patterning over a photoelectric converting material or a color filter material, and furthermore, can be utilized for defining a pixel to have an optional shape.

In the non-translucent insulator according to the invention, furthermore, it is possible to considerably reduce the electrostatic capacity of the peripheral portion of a pixel by setting a thickness thereof to be sufficiently greater than the thickness of the photoelectric converting region. Thus, it is possible to carry out the read of information with a high sensitivity which is less influenced by a parasitic capacitance.

### EXAMPLE 1

First of all, an ITO film having a thickness of 160 nm was formed on a glass substrate by a sputtering process, a resist material (OFPR-800 produced by TOKYO OHKA KOGYO CO., LTD.) was then applied onto the ITO film by a spin coating process to form a resist film having a thickness of 10 μm, and masking, exposure and development were carried out to pattern the resist film to have a predetermined shape. Next, the glass substrate was immersed in 50% hydrochloric acid at 60° C. and the ITO film in a portion in which the resist film is not formed was etched, and thereafter, the resist film was also removed. Consequently, there was obtained a glass substrate in which a first anode formed by an ITO film having a pattern with a line number=176 and a pitch=0.198 mm is provided.

Subsequently, the glass substrate was subjected to a cleaning treatment in order of ultrasonic cleaning for 5 minutes by a detergent (SEMICO CLEAN produced by FURUUCHI KAGAKU CO., LTD.), ultrasonic cleaning for 10 minutes by pure water, ultrasonic cleaning for 5 minutes by using a solution obtained by mixing 1 of aqueous hydrogen peroxide and 5 of water with 1 of ammonia water (volume ratio), and ultrasonic cleaning for 5 minutes by pure water at 70° C., and water sticking to the glass substrate was then removed by means of a nitrogen blower, and furthermore, the glass substrate was heated to 250° C. and was thus dried.

Next, TPD was formed in a thickness of approximately 50 nm as a hole transporting layer on a surface at the anode side of the glass substrate in a resistance heating deposition device in which a pressure is reduced to a degree of vacuum of 2×10⁻⁶ Torr or less.

Furthermore, Alq₃ was formed in a thickness of approximately 60 nm as a light emitting layer on the hole transporting layer in the resistance heating deposition device in the same manner. Both the deposition speeds of TPD and Alq₃ were 0.2 nm/s.

Next, the deposition mask of a pattern with a line number=176 and a pitch=0.198 mm was adhered by using a magnet in the resistance heating deposition device in the same manner, and LiF having a thickness of 1 nm, and subsequently, Al having a thickness of 150 nm were deposited on a light emitting layer through the deposition mask, thereby forming a cathode. Consequently, an organic electroluminescence simple matrix panel of 176×176 dots was obtained.

Then, an AlN film having a thickness of 5 nm, and subsequently, a SiO₂ film having a thickness of 50 nm were formed on the matrix panel by a sputtering process so that an electric insulating layer was provided. Furthermore, an ITO film having a thickness of 100 nm was formed on the electric insulating layer by the sputtering process.

Subsequently, the substrate was taken out of a vacuum chamber, and poly(3,4) ethylenedioxythiophene/polystyrene sulfonate (PEDT/PSS) was dropped onto an upper part through a 0.45 μm filter and was applied uniformly by a spin coating process. This was heated for 10 minutes in a clean oven at 200° C. so that a buffer layer was formed.

Next, a chlorobenzene solution having a weight ratio of 1:4 of poly(2-methoxy-5-(2′-ethylhexyloxy)-1,4-phenylenevinylene (MEH-PPV) and [5,6]-phenyl C61 butylic acid methylester ([5,6]-PCBM) was subjected to spin coating and was then subjected to a heating treatment for 30 minutes in the clean oven at 100° C. so that a photoelectric converting layer having a thickness of approximately 100 nm was formed.

Finally, LiF having a thickness of approximately 1 nm, and subsequently, Al having a thickness of approximately 10 nm were formed on the photoelectric converting layer in a resistance heating deposition device in which a pressure is reduced to a degree of vacuum of 0.27 mPa (=2×10⁻⁶ Torr) or less. Thus, an organic photoelectric converting unit was obtained.

In conclusion, a glass plate was bonded onto the organic photoelectric converting unit by means of a photocuring epoxy resin. Thus, an information reading unit suppressing the invasion of water was obtained.

The present disclosure relates to subject matter contained in priority Japanese Patent Application No. 2003-31213 filed on Feb. 7, 2003, Japanese Patent Application No. 2003-433142 filed on Dec. 26, 2003, and Japanese Patent Application No. 2004-084377 filed on Mar. 23, 2004, the contents of which are herein expressly incorporated by reference in its entirety.

According to the present invention, an organic information reading sensor can be produced in low cast and with easy process, and realize high-resolution and high-quality reading with suppressing influence of stray light in the sensor. Thus, the present invention is preferable for an information reading device for reading out information such as text, symbols, or graphics.

1. An organic information reading sensor comprising a plurality of light receiving sections for interposing at least one kind of organic material between electrodes and converting a light signal into an electric signal, wherein a non-translucent insulator is provided between the light receiving sections.

2. The organic information reading sensor according to claim 1, wherein the light receiving sections are isolated perfectly from each other through the non-translucent insulator.

3. The organic information reading sensor according to claim 1, wherein when a thickness of the non-translucent insulator is represented by ti and a thickness of the light receiving section is represented by td, ti≧td is satisfied.

4. The organic information reading sensor according to claim 1, wherein the light receiving sections have individual light emitting sections, respectively.

5. The organic information reading sensor according to claim 1, wherein the light receiving sections and the light emitting sections are laminated.

6. The organic information reading sensor according to claim 1, wherein the light receiving sections have individual lens arrays, respectively.

7. The organic information reading sensor according to claim 6, wherein the lens arrays are separated from each other through the non-translucent insulator.

8. The organic information reading sensor according to claim 1, wherein the light receiving section includes an organic photoelectric converting unit having a photoelectric converting region formed by at least two electrodes on a substrate, at least one kind of electron donating organic material between the electrodes, and an electron accepting material containing fullerenes and/or carbon nano tubes.

9. An information reading device using the organic information reading sensor according to claim 1.

10. A method of manufacturing an organic information reading sensor comprising a plurality of light receiving sections for interposing at least one kind of organic material between electrodes and converting a light signal into an electric signal and provided with a non-translucent insulator between the light receiving sections,
wherein the non-translucent insulator is formed before the light receiving sections.

11. An information reading unit comprising:
a light emitting section which irradiates a light on an object;
a plurality light receiving sections, each converts a light reflected from the object into an electric signal; and
a non-translucent insulator is provided between the light receiving sections, wherein at least a part of the light receiving section has a light transmitting property, and the light receiving section and the light emitting section are laminated.

12. An information reading unit as claimed in claim 11, wherein the light receiving section and the light emitting section are provided on the same optical axis.

13. The information reading unit according to claim 11, wherein the light receiving section comprises an organic photoelectric converting unit having a photoelectric charge generating region formed by at least one type of electron donating organic material and electron accepting material between electrodes.

14. An information reading device using the organic information reading sensor according to claim 2.

15. An information reading device using the organic information reading sensor according to claim 3.

16. An information reading device using the organic information reading sensor according to claim 4.

17. An information reading device using the organic information reading sensor according to claim 5.

18. An information reading device using the organic information reading sensor according to claim 6.

19. An information reading device using the organic information reading sensor according to claim 7.

20. An information reading device using the organic information reading sensor according to claim 8.
